(19) United States
(12) Patent Application Publication
(10) Pub. No.: US 2024/0118826 A1
(43) Pub. Date: Apr. 11, 2024

(54) MEMORY ARRAY UTILIZING BITCELLS WITH SINGLE-ENDED READ CIRCUITRY

(71) Applicant: Intel Corporation, Santa Clara, CA (US)

(72) Inventors: Amlan Ghosh, Mebane, NC (US); Feroze Merchant, Austin, TX (US); Jaydeep Kulkarni, Austin, TX (US); John R. Riley, Sebastian, FL (US)

(21) Appl. No.: 17/963,313

(22) Filed: Oct. 11, 2022

(51) Int. Cl. G06F 3/06

(52) U.S. Cl. CPC G06F 3/0655; G06F 3/0604; G06F 3/0679

(57) ABSTRACT

A memory device includes at least one bitcell coupled to a local bitline. The at least one bitcell includes multiple sets of a plurality of transistor devices. The first set of the plurality of transistor devices is configured to form a single write (1W) port for receiving digital data. The second set of the plurality of transistor devices is configured as an inverter pair. The inverter pair stores the digital data. The third set of the plurality of transistor devices is configured to form a single read (1R) port. The 1R port can be used to access the digital data stored at the inverter pair and output the digital data on the local bitline. The plurality of transistor devices includes an equal number of P-channel transistor devices and N-channel transistor devices.

### TECHNICAL FIELD

Embodiments pertain to improvements in memory architectures, including techniques for high-density high-performance memory arrays utilizing one or more bitcells (e.g., one or more eight-transistor (8T) bitcells) having balanced, fully populated P-N type semiconductor diffusion layouts with single-ended read circuitry.

### BACKGROUND

With the increased use of memory devices, further performance improvements in processing efficiency and implementation footprint are relevant considerations. Conventional memory arrays are typically associated with layout transition region spacing and reduced utilization of the available diffusion space, which increases the implementation footprint and reduces area efficiency.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a block diagram of a radio architecture including an interface card with a memory device configured according to disclosed techniques, in accordance with some embodiments;

FIG. 2 illustrates a front-end module circuitry for use in the radio architecture of FIG. 1, in accordance with some embodiments;

FIG. 3 illustrates a radio IC circuitry for use in the radio architecture of FIG. 1, in accordance with some embodiments;

FIG. 4 illustrates a baseband processing circuitry for use in the radio architecture of FIG. 1, in accordance with some embodiments;

FIG. 5 illustrates an example computing system with a memory device configured according to disclosed techniques, in accordance with some embodiments;

FIG. 6 illustrates a block diagram of an example processor and/or SoC that may have one or more cores, an integrated memory controller, and a memory device configured according to disclosed techniques, in accordance with some embodiments;

FIG. 7 is a block diagram illustrating both an example in-order pipeline and an example register renaming, out-of-order issue/execution pipeline in accordance with some embodiments;

FIG. 8 is a block diagram illustrating both an example in-order architecture core and an example register renaming, out-of-order issue/execution architecture core to be included in a processor in accordance with some embodiments;

FIG. 9 illustrates an 8T domino bitcell configured as a one-read-port-one-write-port (1R1W) bitcell, in accordance with some embodiments;

FIG. 10 illustrates a 12T static RF bitcell with interrupted write and isolation inverter in the read port, in accordance with some embodiments;

FIG. 11 illustrates a balanced P/N 8T bitcell configured as 1R1W bitcell with a single-ended read mechanism, in accordance with some embodiments;

FIG. 12 illustrates a schematic diagram of a 256-entry bundle using 1R1W bitcells and a single-ended, mid-rail read operation, in accordance with some embodiments;

FIG. 13 illustrates a graphical representation of signals used by the memory device of FIG. 12 during a read “0” operation, in accordance with some embodiments;

FIG. 14 illustrates a schematic diagram of a different embodiment of a 256-entry bundle using 1R1W bitcells and a single-ended, mid-rail read operation, in accordance with some embodiments;

FIG. 15 illustrates a schematic diagram of a simultaneous pre-charge-evaluate circuit, in accordance with some embodiments;

FIG. 16 illustrates a schematic diagram of a bitcell bundle used by the circuit of FIG. 15, in accordance with some embodiments;

FIG. 17 illustrates a graphical representation of signals used by the circuit of FIG. 15 during a read “0” operation, in accordance with some embodiments;

FIG. 18 illustrates a graphical representation of signals used by the circuit of FIG. 15 during a read “1” operation, in accordance with some embodiments; and

FIG. 19 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for, those of other embodiments. Embodiments outlined in the claims encompass all available equivalents of those claims.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, materials, insulator thicknesses, gate(s) configurations, to mention just a few. Moreover, unless specifically referred to as MOS, TFET, CFET, or other, the term transistor can encompass other suitable transistor types, e.g., junction-field-effect transistors, bipolar-junction transistors, metal semiconductor FETs, and various types of three dimensional transistors, known today or not yet developed.

The term “channel” refers to a transmission path through which a signal (X(t) in the depicted figure) propagates from a transmitter output to a receiver input. It may include combinations of conductive traces, wireless paths, and/or optical transmission media. For example, it could include combinations of packaging components (e.g., bond wires, solder balls), package traces, sockets, printed-circuit board (PCB) traces, cables (e.g., coaxial, ribbon, twisted pair), wave guides, air (and any other wireless transmission media), optical cable (and other optical transmission components), and so on. It may also include higher level components for driving, routing, and/or switching signals onto or off of the channel.

As used herein, the term “chip” (or die) refers to a piece of a material, such as a semiconductor material, that includes a circuit such as an integrated circuit or a part of an integrated circuit.

A chiplet is an integrated circuit block that has been designed to work with other chiplets to form larger more complex processing modules. In such modules, a system is subdivided into circuit blocks, called “chiplets”, that are often made of reusable IP blocks. They typically are formed on a single semiconductor die but may comprise multiple dies or die components. A benefit of employing chiplets to make a processing module is that they may be formed from different process node with different associated strengths, costs, etc. In addition, in many cases, it is easier to make smaller chiplets forming a larger, overall processing system rather than implementing the system on a single die.

The disclosed techniques can be used to configure memory devices to address the following technical deficiencies of existing memory device technologies: (a) Bitcell area: utilize 100% of the available diffusion space for active transistors to minimize the bitcell area; (b) Scalability: develop a scalable bitcell topology with an equal number of P/N which can effectively leverage future Complementary FET (CFET) technology (with P device implemented on top of an NFET or vice versa) for aggressive area scaling; (c) Array efficiency: eliminate the transition region layout spacing typically used between the peripheral standard logic cells and custom 8T Static Random Access Memory (SRAM) bitcell having non-standard cell height layout; and (d) Functionality: enabling multi-port functionality in a small footprint.

In some aspects, memory device technologies enable multi-port bitcell functionality by increasing the clock frequency by 2X by using a one-read-one-write (1R1W) bitcell at the expense of increased read power, use a larger area bitcell with domino-read decoupled 2R1W bitcell, and insert transition region area between the standard cells and the custom 8T SRAM layout regions. However, such memory device technologies may be associated with the following drawbacks: (a) Significant area overhead with transition regions between the custom 8T SRAM bitcell and the standard logic cell height; (b) Area scaling limited in modern/future CMOS technologies due to unbalanced use of P and N type transistors; and (c) Increased area overhead for baseline domino-read bitcell in future CFET technologies due to N-dominated bitcell.

In some aspects, 1R1W 8T bitcell has two P-channel metal-oxide semiconductor (PMOS) transistors and six N-channel metal-oxide semiconductor (NMOS) transistors leading to inefficient layout. Such bitcell also has design rules to accommodate the unequal number of N/P devices and may need special transition regions when interfacing to standard logic. Such configurations can lead to poor area utilization. In some aspects, alternate solutions utilize a static CMOS bitcell. This bitcell, however, can be configured with ten transistors to ensure correct functionality and performance of a 1R1W cell. The addition of two transistors over the 8T bitcell also leads to area inefficiency. The design of such cell can be inefficient in terms of performance as it gives up the benefit of a domino read port in favor of a static CMOS. In this regard, existing bitcell technologies may be associated with inefficient area use due to significant overhead in transition regions between an NMOS-heavy bitcell and standard logic cells as well use of additional transistors in the bitcell design.

The disclosed techniques use a bitcell which is a variant of a static CMOS bitcell. The disclosed bitcell is based on a 10-transistor 1R1W cell with 2 transistors in the read path being removed. This configuration leads to a bitcell which is no longer read stable. The disclosed techniques further use a read bitline strategy which pre-charges the bitline to 50% Vcc. The pre-charge to ½ Vcc has two advantages: (i) the read stability of the cell is improved; and (ii) the read performance of the cell is also improved as read processing can be based on a transition from ½ Vcc to full Vcc (e.g., on a read of “1”), or from ½ Vcc to Vss (e.g., on a read of “0”). In this regard, the disclosed techniques provide 40% read delay performance over current state of the art at high performance as well as low voltage corner without any area or dynamic power overhead. The disclosed techniques also provide 33% area improvement and 40% performance improvement over a traditional static CMOS bitcell.

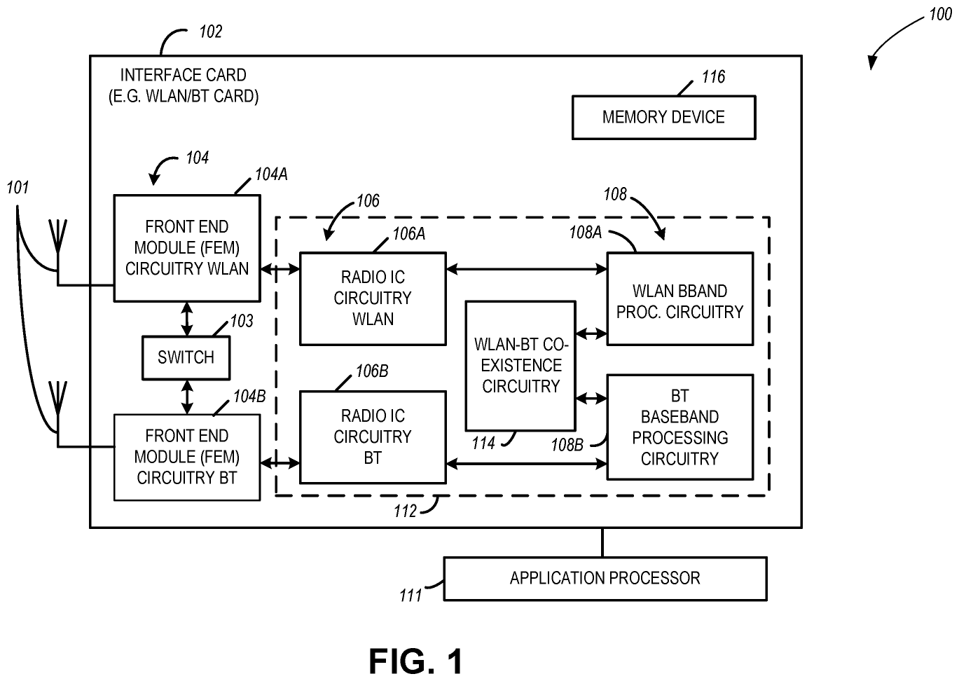

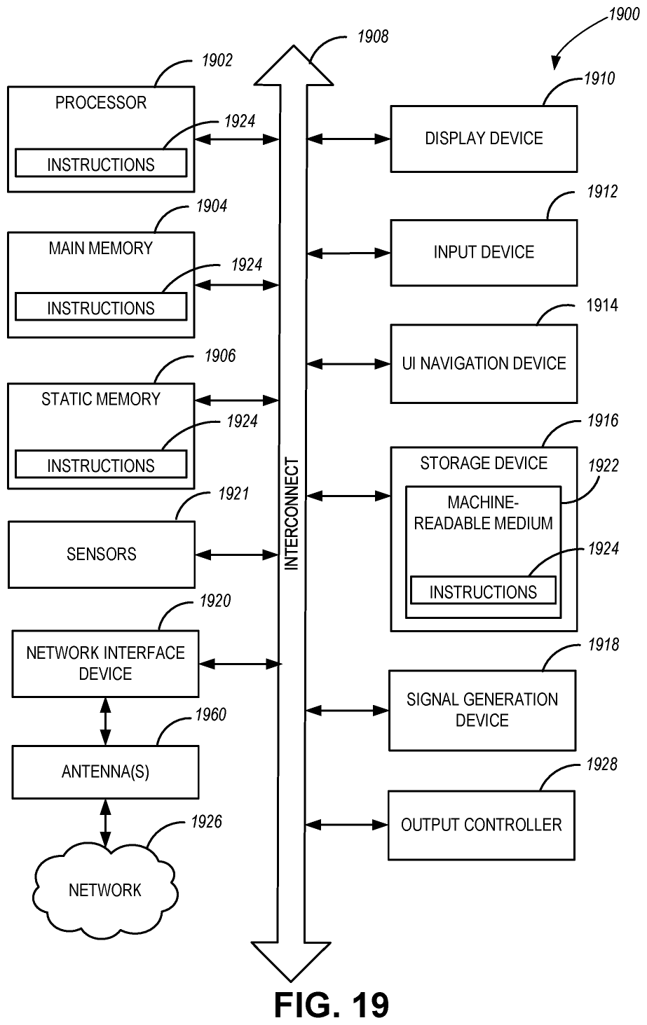

FIG. 1 is a block diagram of a radio architecture 100 including an interface card 102 with a memory device 116, in accordance with some embodiments. The radio architecture 100 may be implemented in a computing device (e.g., device 1900 in FIG. 19) including user equipment (UE), a base station (e.g., a next generation Node-B (gNB), enhanced Node-B (eNB)), a smartphone, a personal computer (PC), a laptop, a tablet, or another type of wired or wireless device. The radio architecture 100 may include radio front-end module (FEM) circuitry 104, radio integrated circuit (IC) circuitry 106, memory device 116, and baseband processing circuitry 108 configured as part of the interface card 102. In this regard, radio architecture 100 (as shown in FIG. 1) includes an interface card 102 configured to perform both Wireless Local Area Network (WLAN) functionalities and Bluetooth (BT) functionalities (e.g., as WLAN/BT interface or modem card), although embodiments are not so limited and the disclosed techniques apply to other types of radio architectures with different types of interface cards as well. In this disclosure, “WLAN” and “Wi-Fi” are used interchangeably. Other example types of interface cards which can be used in connection with the disclosed techniques include graphics cards, network cards, SSD cards (such as M.2-based cards), CEM-based cards, etc.

FEM circuitry 104 may include a WLAN or Wi-Fi FEM circuitry 104A and a Bluetooth (BT) FEM circuitry 104B. The WLAN FEM circuitry 104A may include a receive signal path comprising circuitry configured to operate on WLAN RF signals received from one or more antennas 101, to amplify the received signals, and provide the amplified versions of the received signals to the WLAN radio IC circuitry 106A for further processing. The BT FEM circuitry 104B may include a receive signal path which may include circuitry configured to operate on BT RF signals received from the one or more antennas 101, to amplify the received signals, and provide the amplified versions of the received signals to the BT radio IC circuitry 106B for further processing. The WLAN FEM circuitry 104A may also include a transmit signal path which may include circuitry configured to amplify WLAN signals provided by the radio IC circuitry 106A for wireless transmission by the one or more antennas 101. Besides, the BT FEM circuitry 104B may also include a transmit signal path which may include circuitry configured to amplify BT signals provided by the radio IC circuitry 106B for wireless transmission by the one or more antennas. In the embodiment of FIG. 1, although WLAN FEM circuitry 104A and BT FEM circuitry 104B are shown as being distinct from one another, embodiments are not so limited and include within their scope the use of a FEM (not shown) that includes a transmit path and/or a receive path for both WLAN and BT signals, or the use of one or more FEM circuitries where at least some of the FEM circuitries share transmit and/or receive signal paths for both WLAN and BT signals.

Radio IC circuitry 106 as shown may include WLAN radio IC circuitry 106A and BT radio IC circuitry 106B. The WLAN radio IC circuitry 106A may include a receive signal path which may include circuitry to down-convert WLAN RF signals received from the WLAN FEM circuitry 104A and provide baseband signals to WLAN baseband processing circuitry 108A. The BT radio IC circuitry 106B may, in turn, include a receive signal path which may include circuitry to down-convert BT RF signals received from the BT FEM circuitry 104B and provide baseband signals to BT baseband processing circuitry 108B. The WLAN radio IC circuitry 106A may also include a transmit signal path which may include circuitry to up-convert WLAN baseband signals provided by the WLAN baseband processing circuitry 108A and provide WLAN RF output signals to the WLAN FEM circuitry 104A for subsequent wireless transmission by the one or more antennas 101. The BT radio IC circuitry 106B may also include a transmit signal path which may include circuitry to up-convert BT baseband signals provided by the BT baseband processing circuitry 108B and provide BT RF output signals to the BT FEM circuitry 104B for subsequent wireless transmission by the one or more antennas 101. In the embodiment of FIG. 1, although radio IC circuitries 106A and 106B are shown as being distinct from one another, embodiments are not so limited and include within their scope the use of a radio IC circuitry (not shown) that includes a transmit signal path and/or a receive signal path for both WLAN and BT signals, or the use of one or more radio IC circuitries where at least some of the radio IC circuitries share transmit and/or receive signal paths for both WLAN and BT signals.

Baseband processing circuitry 108 may include a WLAN baseband processing circuitry 108A and a BT baseband processing circuitry 108B. The WLAN baseband processing circuitry 108A may include a memory, such as, for example, a set of RAM arrays in a Fast Fourier Transform (FFT) or Inverse Fast Fourier Transform (IFFT) block (not shown) of the WLAN baseband processing circuitry 108A. Each of the WLAN baseband processing circuitry 108A and the BT baseband processing circuitry 108B may further include one or more processors and control logic to process the signals received from the corresponding WLAN or BT receive signal path of the radio IC circuitry 106, and to also generate corresponding WLAN or BT baseband signals for the transmit signal path of the radio IC circuitry 106. Each of the baseband processing circuitries 108A and 108B may further include a physical layer (PHY) and medium access control layer (MAC) circuitry and may further interface with a host processor (e.g., the application processor 111) in a host system (e.g., a host SoC) for generation and processing of the baseband signals and for controlling operations of the radio IC circuitry 106 (including controlling the operation of the memory device 116).

Referring still to FIG. 1, according to the shown embodiment, WLAN-BT coexistence circuitry 114 may include logic providing an interface between the WLAN baseband processing circuitry 108A and the BT baseband processing circuitry 108B to enable use cases requiring WLAN and BT coexistence. In addition, a switch 103 may be provided between the WLAN FEM circuitry 104A and the BT FEM circuitry 104B to allow switching between the WLAN and BT radios according to application needs. In addition, although the one or more antennas 101 are depicted as being respectively connected to the WLAN FEM circuitry 104A and the BT FEM circuitry 104B, embodiments include within their scope the sharing of the one or more antennas 101 as between the WLAN and BT FEMs, or the provision of more than one antenna connected to each of FEM circuitries 104A or 104B.

In some embodiments, the front-end module circuitry 104, the radio IC circuitry 106, and the baseband processing circuitry 108 may be provided on a single radio card, such as the interface card 102. In some other embodiments, the one or more antennas 101, the FEM circuitry 104, and the radio IC circuitry 106 may be provided on a single radio card. In some other embodiments, the radio IC circuitry 106 and the baseband processing circuitry 108 may be provided on a single chip or IC, such as IC 112.

In some embodiments, the interface card 102 can be configured as a wireless radio card, such as a WLAN radio card configured for wireless communications (e.g., WiGig communications in the 60 GHz range or mmW communications in the 24.24 GHz-52.6 GHz range), although the scope of the embodiments is not limited in this respect. In some of these embodiments, the radio architecture 100 may be configured to receive and transmit orthogonal frequency division multiplexed (OFDM) or orthogonal frequency division multiple access (OFDMA) communication signals over a multicarrier communication channel. The OFDM or OFDMA signals may comprise a plurality of orthogonal subcarriers.

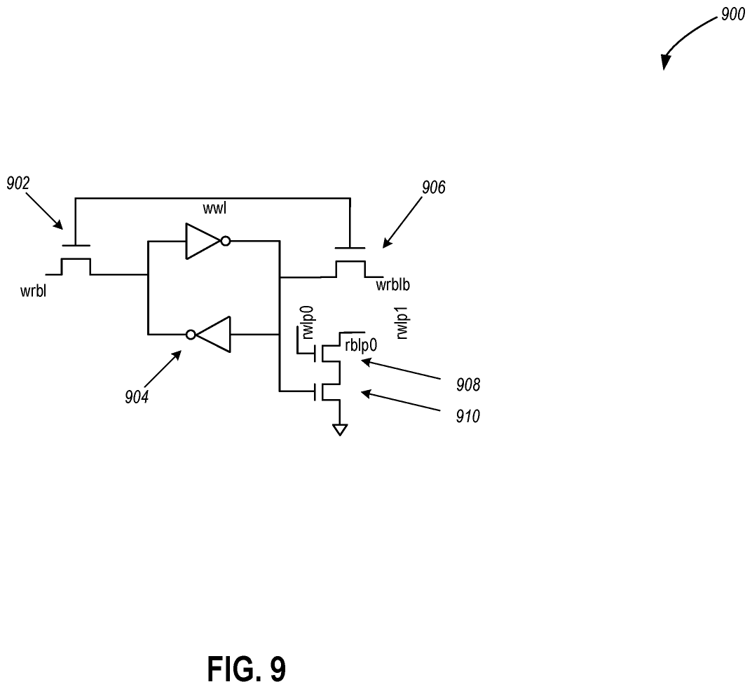

In some embodiments, the interface card 102 may include one or more memory devices such as memory device 116. Memory device 116 can be configured based on the disclosed techniques. In this regard, memory device 116 can be the same as, or include, one or more of the memory devices discussed in connection with FIGS. 9-18.

In some of these multicarrier embodiments, radio architecture 100 may be part of a Wi-Fi communication station (STA) such as a wireless access point (AP), a base station, or a mobile device including a Wi-Fi enabled device. In some of these embodiments, radio architecture 100 may be configured to transmit and receive signals in accordance with specific communication standards and/or protocols, such as any of the Institute of Electrical and Electronics Engineers (IEEE) standards including, 802.11n-2009, IEEE 802.11-2012, 802.11n-2009, 802.11ac, IEEE 802.11-2016, 802.11ad, and/or 802.11ax standards and/or proposed specifications for WLANs, although the scope of embodiments is not limited in this respect and operations using other wireless standards can also be configured. Radio architecture 100 may also be suitable to transmit and/or receive communications in accordance with other techniques and standards, including a 3rd Generation Partnership Project (3GPP) standard, including a communication standard used in connection with 5G or new radio (NR) communications.

In some embodiments, the radio architecture 100 may be configured for high-efficiency (HE) Wi-Fi communications in accordance with the IEEE 802.11ax standard or another standard associated with wireless communications. In these embodiments, the radio architecture 100 may be configured to communicate in accordance with an OFDMA technique, although the scope of the embodiments is not limited in this respect.

In some other embodiments, the radio architecture 100 may be configured to transmit and receive signals transmitted using one or more other modulation techniques such as spread spectrum modulation (e.g., direct sequence code division multiple access (DS-CDMA) and/or frequency hopping code division multiple access (FH-CDMA)), time-division multiplexing (TDM) modulation, and/or frequency-division multiplexing (FDM) modulation, although the scope of the embodiments is not limited in this respect.

In some embodiments, as further shown in FIG. 1, the BT baseband processing circuitry 108B may be compliant with a Bluetooth (BT) connectivity standard such as Bluetooth, Bluetooth 4.0 or Bluetooth 5.0, or any other iteration of the Bluetooth Standard. In embodiments that include BT functionality as shown for example in FIG. 1, the radio architecture 100 may be configured to establish a BT synchronous connection-oriented (SCO) link and or a BT low energy (BT LE) link. In some of the embodiments that include functionality, the radio architecture 100 may be configured to establish an extended SCO (eSCO) link for BT communications, although the scope of the embodiments is not limited in this respect. In some of these embodiments that include a BT functionality, the radio architecture may be configured to engage in a BT Asynchronous Connection-Less (ACL) communications, although the scope of the embodiments is not limited in this respect. In some embodiments, as shown in FIG. 1, the functions of a BT radio card and WLAN radio card may be combined on a single wireless radio card, such as the interface card 102, although embodiments are not so limited, and include within their scope discrete WLAN and BT radio cards.

In some embodiments, the radio architecture 100 may include other radio cards, such as a cellular radio card configured for cellular/wireless communications (e.g., 3GPP such as LTE, LTE-Advanced, WiGig, or 5G communications including mmW communications), which may be implemented together with (or as part of) the interface card 102.

In some IEEE 802.11 embodiments, the radio architecture 100 may be configured for communication over various channel bandwidths including bandwidths having center frequencies of about 900 MHz, 2.4 GHz, 5 GHz, and bandwidths of about 1 MHz, 2 MHz, 2.5 MHz, 4 MHz, 5 MHz, 8 MHz, 10 MHz, 16 MHz, 20 MHz, 40 MHz, 80 MHz (with contiguous bandwidths) or 80+80 MHz (160 MHz) (with non-contiguous bandwidths). In some embodiments, a 320 MHz channel bandwidth may be used. The scope of the embodiments is not limited with respect to the above center frequencies, however.

In some embodiments, memory device 116 is configured as cache memory, including array and queues used in high performance microprocessor CPU/GPU designs. Other use cases of the disclosed memory devices can be configured as well.

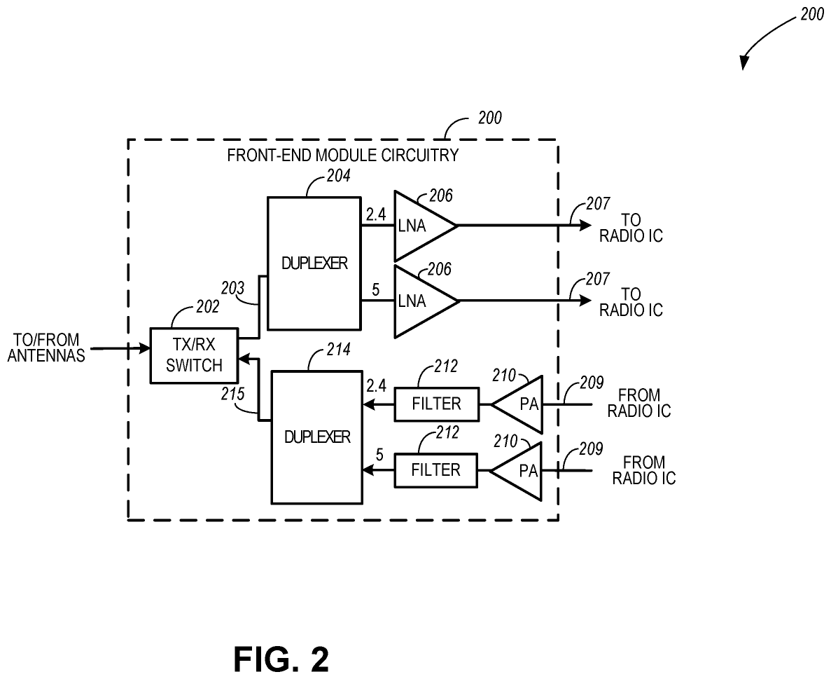

FIG. 2 illustrates FEM circuitry 200 in accordance with some embodiments. The FEM circuitry 200 is one example of circuitry that may be suitable for use as the WLAN and/or BT FEM circuitry 104A/104B (FIG. 1), although other circuitry configurations may also be suitable.

In some embodiments, the FEM circuitry 200 may include a TX/RX switch 202 to switch between transmit (TX) mode and receive (RX) mode operation. In some aspects, a diplexer may be used in place of a TX/RX switch. The FEM circuitry 200 may include a receive signal path and a transmit signal path. The receive signal path of the FEM circuitry 200 may include a low-noise amplifier (LNA) 206 to amplify received RF signals 203 and provide the amplified received RF signals 207 as an output (e.g., to the radio IC circuitry 106 (FIG. 1)). The transmit signal path of the FEM circuitry 200 may include a power amplifier (PA) to amplify input RF signals 209 (e.g., provided by the radio IC circuitry 106), and one or more filters 212, such as band-pass filters (BPFs), low-pass filters (LPFs) or other types of filters, to generate RF signals 215 for subsequent transmission (e.g., by the one or more antennas 101 (FIG. 1)).

In some dual-mode embodiments for Wi-Fi communication, the FEM circuitry 200 may be configured to operate in, e.g., either the 2.4 GHz frequency spectrum or the 5 GHz frequency spectrum. In these embodiments, the receive signal path of the FEM circuitry 200 may include a receive signal path duplexer 204 to separate the signals from each spectrum as well as provide a separate LNA 206 for each spectrum as shown. In these embodiments, the transmit signal path of the FEM circuitry 200 may also include a power amplifier (PA) 210 and one or more filters 212, such as a BPF, an LPF, or another type of filter for each frequency spectrum, and a transmit signal path duplexer 214 to provide the signals of one of the different spectrums onto a single transmit path for subsequent transmission by the one or more antennas 101 (FIG. 1). In some embodiments, BT communications may utilize the 2.4 GHz signal path and may utilize the same FEM circuitry 200 as the one used for WLAN communications.

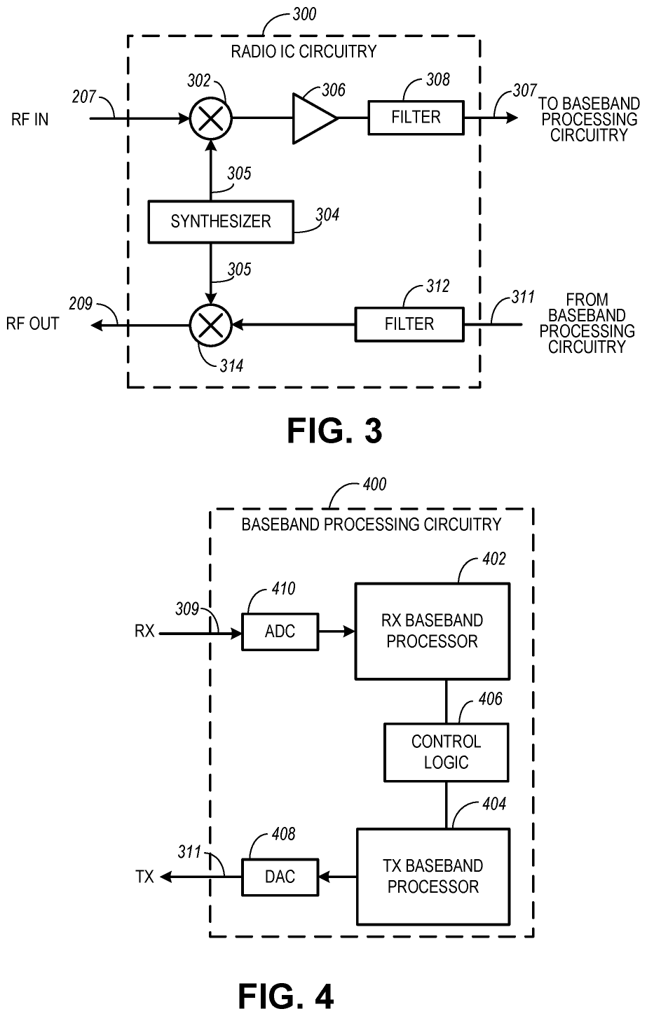

FIG. 3 illustrates radio IC circuitry 300 in accordance with some embodiments. The radio IC circuitry 300 is one example of circuitry that may be suitable for use as the WLAN or BT radio IC circuitry 106A/106B (FIG. 1), although other circuitry configurations may also be suitable.

In some embodiments, the radio IC circuitry 300 may include a receive signal path and a transmit signal path. The receive signal path of the radio IC circuitry 300 may include mixer circuitry 302, such as, for example, down-conversion mixer circuitry, amplifier circuitry 306, and filter circuitry 308. The transmit signal path of the radio IC circuitry 300 may include at least filter circuitry 312 and mixer circuitry 314, such as up-conversion mixer circuitry. Radio IC circuitry 300 may also include synthesizer circuitry 304 for synthesizing a frequency 305 for use by the mixer circuitry 302 and the mixer circuitry 314. The mixer circuitry 302 and/or 314 may each, according to some embodiments, be configured to provide direct conversion functionality. The latter type of circuitry presents a much simpler architecture as compared with standard super-heterodyne mixer circuitries, and any flicker noise brought about by the same may be alleviated for example through the use of OFDM modulation. FIG. 3 illustrates only a simplified version of a radio IC circuitry and may include, although not shown, embodiments where each of the depicted circuitries may include more than one component. For instance, mixer circuitry 302 and/or 314 may each include one or more mixers, and filter circuitries 308 and/or 312 may each include one or more filters, such as one or more BPFs and/or LPFs according to application needs. For example, when mixer circuitries are of the direct-conversion type, they may each include two or more mixers.

In some embodiments, mixer circuitry 302 may be configured to down-convert RF signals 207 received from the FEM circuitry 104 (FIG. 1) based on the synthesized frequency 305 provided by the synthesizer circuitry 304. The amplifier circuitry 306 may be configured to amplify the down-converted signals and the filter circuitry 308 may include an LPF configured to remove unwanted signals from the down-converted signals to generate output baseband signals 307. Output baseband signals 307 may be provided to the baseband processing circuitry 108 (FIG. 1) for further processing. In some embodiments, the output baseband signals 307 may be zero-frequency baseband signals, although this is not a requirement. In some embodiments, mixer circuitry 302 may comprise passive mixers, although the scope of the embodiments is not limited in this respect.

In some embodiments, the mixer circuitry 314 may be configured to up-convert input baseband signals 311 based on the synthesized frequency 305 provided by the synthesizer circuitry 304 to generate RF output signals 209 for the FEM circuitry 104. The baseband signals 311 may be provided by the baseband processing circuitry 108 and may be filtered by filter circuitry 312. The filter circuitry 312 may include an LPF or a BPF, although the scope of the embodiments is not limited in this respect.

In some embodiments, the mixer circuitry 302 and the mixer circuitry 314 may each include two or more mixers and may be arranged for quadrature down-conversion and/or up-conversion respectively with the help of the synthesizer circuitry 304. In some embodiments, the mixer circuitry 302 and the mixer circuitry 314 may each include two or more mixers each configured for image rejection (e.g., Hartley image rejection). In some embodiments, the mixer circuitry 302 and the mixer circuitry 314 may be arranged for direct down-conversion and/or direct up-conversion, respectively. In some embodiments, the mixer circuitry 302 and the mixer circuitry 314 may be configured for super-heterodyne operation, although this is not a requirement.

Mixer circuitry 302 may comprise, according to one embodiment: quadrature passive mixers (e.g., for the in-phase (I) and quadrature-phase (Q) paths). In such an embodiment, RF input signal 207 from FIG. 2 may be down-converted to provide I and Q baseband output signals to be sent to the baseband processor.

Quadrature passive mixers may be driven by zero and ninety-degree time-varying LO switching signals provided by a quadrature circuitry which may be configured to receive a LO frequency (fLO) from a local oscillator or a synthesizer, such as LO frequency 305 of synthesizer circuitry 304 (FIG. 3). In some embodiments, the LO frequency may be the carrier frequency, while in other embodiments, the LO frequency may be a fraction of the carrier frequency (e.g., one-half the carrier frequency, one-third the carrier frequency). In some embodiments, the zero and ninety-degree time-varying switching signals may be generated by the synthesizer, although the scope of the embodiments is not limited in this respect.

In some embodiments, the LO signals may differ in the duty cycle (the percentage of one period in which the LO signal is high) and/or offset (the difference between start points of the period). In some embodiments, the LO signals may have a 25% duty cycle and a 50% offset. In some embodiments, each branch of the mixer circuitry (e.g., the in-phase (I) and quadrature-phase (Q) path) may operate at a 25% duty cycle, which may result in a significant reduction in power consumption.

The RF input signal 207 (FIG. 2) may comprise a balanced signal, although the scope of the embodiments is not limited in this respect. The I and Q baseband output signals may be provided to the low-noise amplifier, such as amplifier circuitry 306 (FIG. 3) or to filter circuitry 308 (FIG. 3).

In some embodiments, the output baseband signals 307 and the input baseband signals 311 may be analog, although the scope of the embodiments is not limited in this respect. In some alternate embodiments, the output baseband signals 307 and the input baseband signals 311 may be digital. In these alternate embodiments, the radio IC circuitry may include an analog-to-digital converter (ADC) and digital-to-analog converter (DAC) circuitry.

In some dual-mode embodiments, a separate radio IC circuitry may be provided for processing signals for each spectrum, or for other spectrums not mentioned here, although the scope of the embodiments is not limited in this respect.

In some embodiments, the synthesizer circuitry 304 may be a fractional-N synthesizer or a fractional N/N+1 synthesizer, although the scope of the embodiments is not limited in this respect as other types of frequency synthesizers may be suitable. In some embodiments, the synthesizer circuitry 304 may be a delta-sigma synthesizer, a frequency multiplier, or a synthesizer comprising a phase-locked loop with a frequency divider. According to some embodiments, the synthesizer circuitry 304 may include a digital frequency synthesizer circuitry. An advantage of using a digital synthesizer circuitry is that, although it may still include some analog components, its footprint may be scaled down much more than the footprint of an analog synthesizer circuitry. In some embodiments, frequency input into synthesizer circuitry 304 may be provided by a voltage-controlled oscillator (VCO), although that is not a requirement. A divider control input may further be provided by either the baseband processing circuitry 108 (FIG. 1) or the host processor 111 (FIG. 1) depending on the desired output frequency 305. In some embodiments, a divider control input (e.g., N) may be determined from a look-up table (e.g., within a Wi-Fi card) based on a channel number and a channel center frequency as determined or indicated by the host processor 111.

In some embodiments, synthesizer circuitry 304 may be configured to generate a carrier frequency as the output frequency 305, while in other embodiments, the output frequency 305 may be a fraction of the carrier frequency (e.g., one-half the carrier frequency, one-third the carrier frequency). In some embodiments, the output frequency 305 may be an LO frequency (fLO).

FIG. 4 illustrates a baseband processing circuitry 400 for use in the radio architecture of FIG. 1, in accordance with some embodiments. The baseband processing circuitry 400 is one example of circuitry that may be suitable for use as the baseband processing circuitry 108 (FIG. 1), although other circuitry configurations may also be suitable. The baseband processing circuitry 400 may include a receive baseband processor (RX BBP) 402 for processing receive baseband signals 309 provided by the radio IC circuitry 106 (FIG. 1) and a transmit baseband processor (TX BBP) 404 for generating transmit baseband signals 311 for the radio IC circuitry 106. The baseband processing circuitry 400 may also include control logic 406 for coordinating the operations of the baseband processing circuitry 400.

In some embodiments (e.g., when analog baseband signals are exchanged between the baseband processing circuitry 400 and the radio IC circuitry 106), the baseband processing circuitry 400 may include an analog-to-digital converter (ADC) 410 to convert analog baseband signals 309 received from the radio IC circuitry 106 to digital baseband signals for processing by the RX BBP 402. In these embodiments, the baseband processing circuitry 400 may also include a digital-to-analog converter (DAC) 408 to convert digital baseband signals from the TX BBP 404 to analog baseband signals 311.

In some embodiments that communicate OFDM signals or OFDMA signals, such as through the WLAN baseband processing circuitry 108A, the TX BBP 404 may be configured to generate OFDM or OFDMA signals as appropriate for transmission by performing an inverse fast Fourier transform (IFFT). The RX BBP 402 may be configured to process received OFDM signals or OFDMA signals by performing an FFT. In some embodiments, the RX BBP 402 may be configured to detect the presence of an OFDM signal or OFDMA signal by performing an autocorrelation, to detect a preamble, such as a short preamble, and performing a cross-correlation, to detect a long preamble. The preambles may be part of a predetermined frame structure for Wi-Fi communication.

Referring back to FIG. 1, in some embodiments, the one or more antennas 101 (FIG. 1) may each comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas may be effectively separated to take advantage of spatial diversity and the different channel characteristics that may result. The one or more antennas 101 may each include a set of phased-array antennas, although embodiments are not so limited.

Although the radio architecture 100 is illustrated as having several separate functional elements, one or more of the functional elements may be combined and may be implemented by combinations of software configured elements, such as processing elements including digital signal processors (DSPs), and/or other hardware elements. For example, some elements may comprise one or more microprocessors, DSPs, field-programmable gate arrays (FPGAs), application-specific integrated circuits (ASICs), radio-frequency integrated circuits (RFICs), and combinations of various hardware and logic circuitry for performing at least the functions described herein. In some embodiments, the functional elements may refer to one or more processes operating on one or more processing elements.

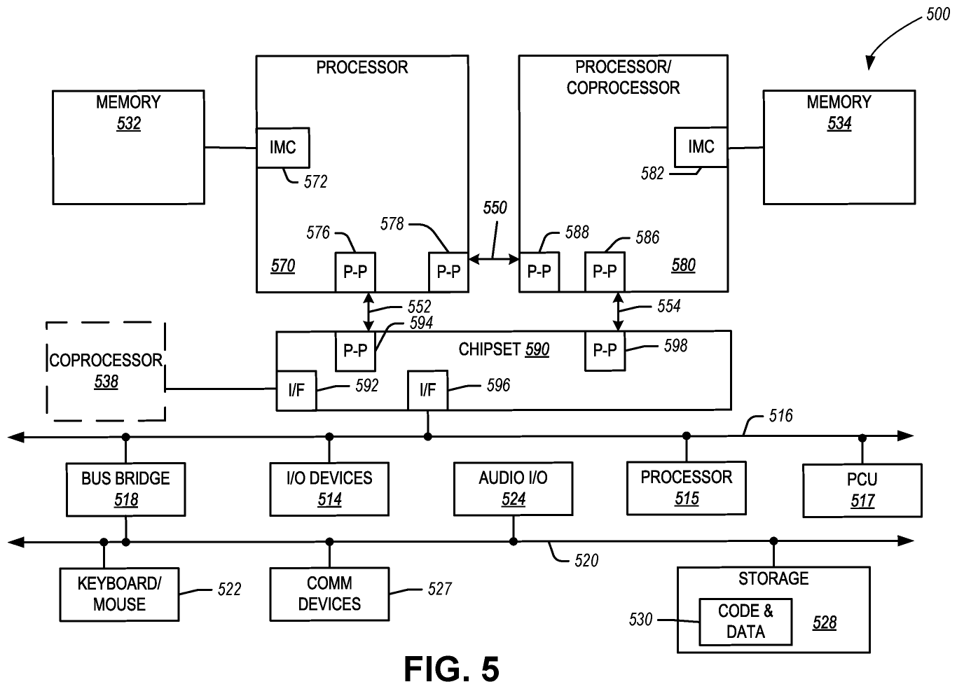

In some aspects (e.g., as discussed in connection with FIGS. 5-8), the disclosed techniques include configuring multi-port, process technology scaling-friendly, balanced P/N 8T bitcells with fully utilized diffusion areas.

FIG. 5 illustrates an example computing system with a memory device configured according to disclosed techniques, in accordance with some embodiments. Multiprocessor system 500 is an interfaced system and includes a plurality of processors including a first processor 570 and a second processor 580 coupled via an interface 550 such as a point-to-point (P-P) interconnect, a fabric, and/or bus. In some examples, the first processor 570 and the second processor 580 are homogeneous. In some examples, first processor 570 and the second processor 580 are heterogenous. Though the example system 500 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 570 and 580 are shown including integrated memory controller (IMC) circuitry 572 and 582, respectively. Processor 570 also includes interface circuits 576 and 578, along with core sets. Similarly, second processor 580 includes interface circuits 586 and 588, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570, 580 may exchange information via the interface 550 using interface circuits 578, 588. IMC circuitry 572 and 582 couple the processors 570, 580 to respective memories, namely a memory 532 and a memory 534, which may be portions of main memory locally attached to the respective processors.

Processors 570, 580 may each exchange information with a network interface (NW I/F) 590 via individual interfaces 552, 554 using interface circuits 576, 594, 586, 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via interface circuit 596. In some examples, first interface 516 may be an interface such as a Peripheral Component Interconnect (PCI) interconnect, a PCI Express interconnect, or another I/O interconnect. In some examples, first interface 516 is coupled to a power control unit (PCU) 517, which may include circuitry, software, and/or firmware to perform power management operations with regard to the processors 570, 580 and/or coprocessor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 517 is illustrated as being present as logic separate from the processor 570 and/or processor 580. In other aspects, PCU 517 may execute on a given one or more of cores (not shown) of processor 570 or 580. In some aspects, PCU 517 may be implemented as a microcontroller (dedicated or general-purpose) or other control logic configured to execute its own dedicated power management code, sometimes referred to as P-code. In yet other aspects, power management operations to be performed by PCU 517 may be implemented externally to a processor, such as by way of a separate power management integrated circuit (PMIC) or another component external to the processor. In yet other embodiments, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 514 may be coupled to first interface 516, along with a bus bridge 518 which couples first interface 516 to a second interface 520. In some examples, one or more additional processor(s) 515, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 516. In some examples, second interface 520 may be a low pin count (LPC) interface. Various devices may be coupled to second interface 520 including, for example, a keyboard and/or mouse 522, communication devices 527, and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; and 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

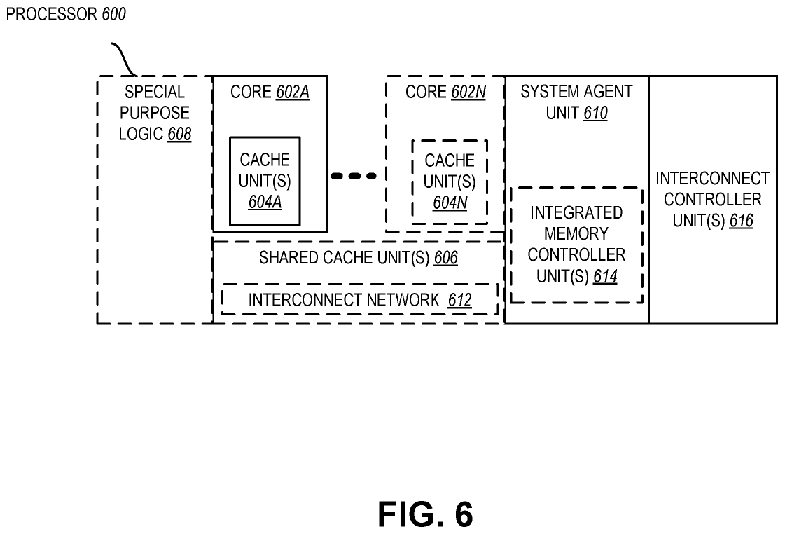

FIG. 6 illustrates a block diagram of an example processor and/or SoC 600 that may have one or more cores, an integrated memory controller, and a memory device configured according to disclosed techniques, in accordance with some embodiments. The solid lined boxes illustrate a processor 600 with a single core 602(A), system agent unit circuitry 610, and a set of one or more interface controller unit(s) circuitry 616, while the optional addition of the dashed lined boxes illustrates an alternative processor 600 with multiple cores 602(A)-(N), a set of one or more integrated memory controller unit(s) circuitry 614 in the system agent unit circuitry 610, and special purpose logic 608, as well as a set of one or more interface controller units circuitry 616. Note that the processor 600 may be one of the processors 570 or 580, or coprocessor 538 or 515 of FIG. 5.

Thus, different implementations of the processor 600 may include: 1) a CPU with the special purpose logic 608 being integrated graphics and/or scientific (throughput) logic (which may include one or more cores, not shown), and the cores 602(A)-(N) being one or more general purpose cores (e.g., general purpose in-order cores, general purpose out-of-order cores, or a combination of the two); 2) a coprocessor with the cores 602(A)-(N) being a large number of special purpose cores intended primarily for graphics and/or scientific (throughput); and 3) a coprocessor with the cores 602(A)-(N) being a large number of general purpose in-order cores. Thus, the processor 600 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 600 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604(A)-(N) within the cores 602(A)-(N), a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2 (L2), level 3 (L3), level 4 (L4), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602(A)-(N). In some examples, interface controller units circuitry 616 couple the cores 602 to one or more other devices such as one or more I/O devices, storage, one or more communication devices (e.g., wireless networking, wired networking, etc.), etc.

In some examples, one or more of the cores 602(A)-(N) are capable of multi-threading. The system agent unit circuitry 610 includes those components coordinating and operating cores 602(A)-(N). The system agent unit circuitry 610 may include, for example, power control unit (PCU) circuitry and/or display unit circuitry (not shown). The PCU may be or may include logic and components needed for regulating the power state of the cores 602(A)-(N) and/or the special purpose logic 608 (e.g., integrated graphics logic). The display unit circuitry is for driving one or more externally connected displays.

The cores 602(A)-(N) may be homogenous in terms of instruction set architecture (ISA). Alternatively, the cores 602(A)-(N) may be heterogeneous in terms of ISA; that is, a subset of the cores 602(A)-(N) may be capable of executing an ISA, while other cores may be capable of executing only a subset of that ISA or another ISA.

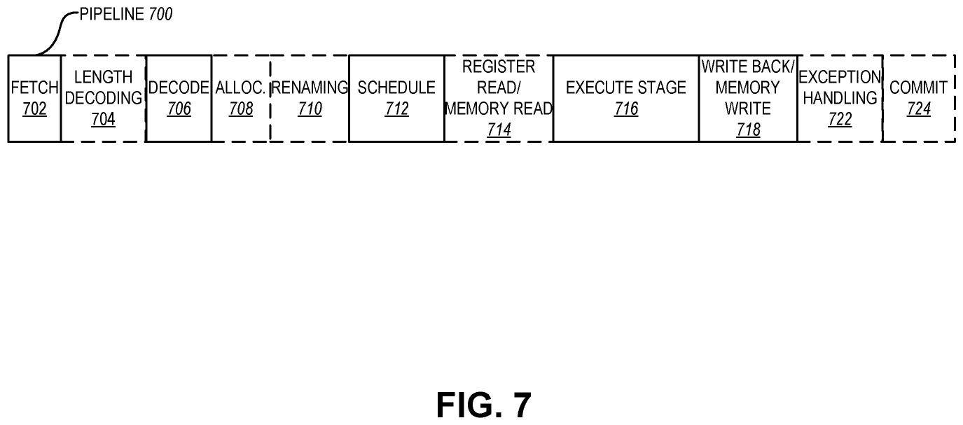

FIG. 7 is a block diagram illustrating both an example in-order pipeline 700 and an example register renaming, out-of-order issue/execution pipeline in accordance with some embodiments;

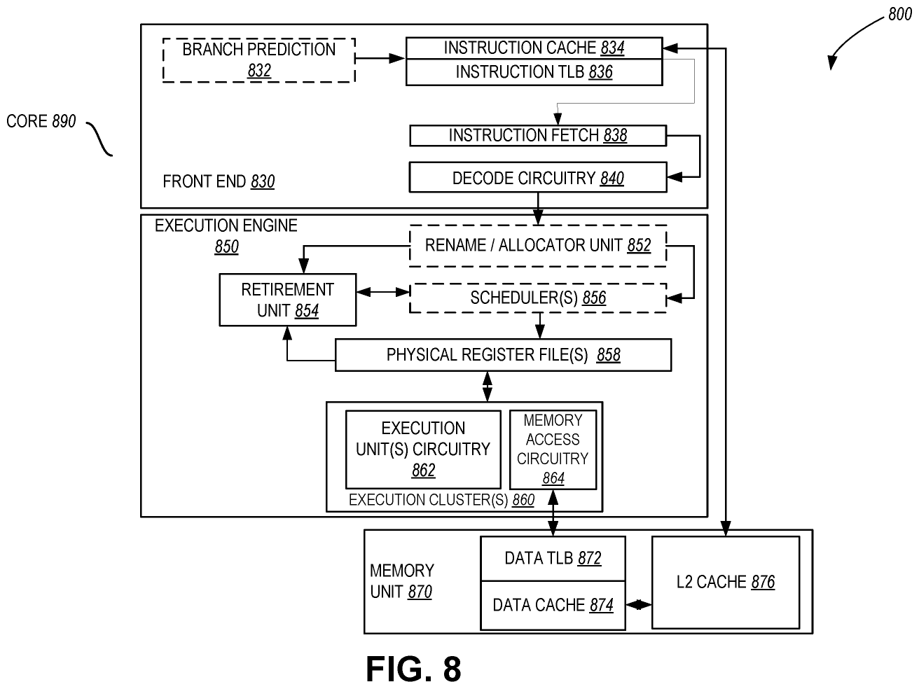

FIG. 8 is a block diagram 800 illustrating both an example in-order architecture core and an example register renaming, out-of-order issue/execution architecture core to be included in a processor in accordance with some embodiments;

The solid lined boxes in FIGS. 7-8 illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 7, a processor pipeline 700 includes a fetch stage 702, an optional length decoding stage 704, a decode stage 706, an optional allocation (Alloc) stage 708, an optional renaming stage 710, a schedule (also known as a dispatch or issue) stage 712, an optional register read/memory read stage 714, an execute stage 716, a write back/memory write stage 718, an optional exception handling stage 722, and an optional commit stage 724. One or more operations can be performed in each of these processor pipeline stages. For example, during the fetch stage 702, one or more instructions are fetched from instruction memory, and during the decode stage 706, the one or more fetched instructions may be decoded, addresses (e.g., load store unit (LSU) addresses) using forwarded register ports may be generated, and branch forwarding (e.g., immediate offset or a link register (LR)) may be performed. In one example, the decode stage 706 and the register read/memory read stage 714 may be combined into one pipeline stage. In one example, during the execute stage 716, the decoded instructions may be executed, LSU address/data pipelining to an Advanced Microcontroller Bus (AMB) interface may be performed, multiply and add operations may be performed, arithmetic operations with branch results may be performed, etc.

By way of example, the example register renaming, out-of-order issue/execution architecture core of FIG. 8 may implement the pipeline 700 as follows: 1) the instruction fetch circuitry 838 performs the fetch and length decoding stages 702 and 704; 2) the decode circuitry 840 performs the decode stage 706; 3) the rename/allocator unit circuitry 852 performs the allocation stage 708 and renaming stage 710; 4) the scheduler(s) circuitry 856 performs the schedule stage 712; 5) the physical register file(s) circuitry 858 and the memory unit circuitry 870 perform the register read/memory read stage 714; the execution cluster(s) 860 perform the execute stage 716; 6) the memory unit circuitry 870 and the physical register file(s) circuitry 858 perform the write back/memory write stage 718; 7) various circuitry may be involved in the exception handling stage 722; and 8) the retirement unit circuitry 854 and the physical register file(s) circuitry 858 perform the commit stage 724.

FIG. 8 shows a processor core 890 including front-end unit circuitry 830 coupled to execution engine unit circuitry 850, and both are coupled to memory unit circuitry 870. The core 890 may be a reduced instruction set architecture computing (RISC) core, a complex instruction set architecture computing (CISC) core, a very long instruction word (VLIW) core, or a hybrid or alternative core type. As yet another option, the core 890 may be a special-purpose core, such as, for example, a network or communication core, compression engine, coprocessor core, general purpose computing graphics processing unit (GPGPU) core, graphics core, or the like.

The front-end unit circuitry 830 may include branch prediction circuitry 832 coupled to instruction cache circuitry 834, which is coupled to an instruction translation lookaside buffer (TLB) 836, which is coupled to instruction fetch circuitry 838, which is coupled to decode circuitry 840. In one example, the instruction cache circuitry 834 is included in the memory unit circuitry 870 rather than the front-end circuitry 830. The decode circuitry 840 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 840 may further include address generation unit (AGU, not shown) circuitry. In one example, the AGU generates an LSU address using forwarded register ports, and may further perform branch forwarding (e.g., immediate offset branch forwarding, LR register branch forwarding, etc.). The decode circuitry 840 may be implemented using various different mechanisms. Examples of suitable mechanisms include, but are not limited to, look-up tables, hardware implementations, programmable logic arrays (PLAs), microcode read only memories (ROMs), etc. In one example, the core 890 includes a microcode ROM (not shown) or other medium that stores microcode for certain macroinstructions (e.g., in decode circuitry 840 or otherwise within the front-end circuitry 830). In one example, the decode circuitry 840 includes a micro-operation (micro-op) or operation cache (not shown) to hold/cache decoded operations, micro-tags, or micro-operations generated during the decode or other stages of the processor pipeline 700. The decode circuitry 840 may be coupled to rename/allocator unit circuitry 852 in the execution engine circuitry 850.

The execution engine circuitry 850 includes the rename/allocator unit circuitry 852 coupled to retirement unit circuitry 854 and a set of one or more scheduler(s) circuitry 856. The scheduler(s) circuitry 856 represents any number of different schedulers, including reservations stations, central instruction window, etc. In some examples, the scheduler(s) circuitry 856 can include arithmetic logic unit (ALU) scheduler/scheduling circuitry, ALU queues, address generation unit (AGU) scheduler/scheduling circuitry, AGU queues, etc. The scheduler(s) circuitry 856 is coupled to the physical register file(s) circuitry 858. Each of the physical register file(s) circuitry 858 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In one example, the physical register file(s) circuitry 858 includes vector registers unit circuitry, writemask registers unit circuitry, and scalar register unit circuitry. These register units may provide architectural vector registers, vector mask registers, general-purpose registers, etc. The physical register file(s) circuitry 858 is coupled to the retirement unit circuitry 854 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 854 and the physical register file(s) circuitry 858 are coupled to the execution cluster(s) 860. The execution cluster(s) 860 includes a set of one or more execution unit(s) circuitry 862 and a set of one or more memory access circuitry 864. The execution unit(s) circuitry 862 may perform various arithmetic, logic, floating-point or other types of operations (e.g., shifts, addition, subtraction, multiplication) and on various types of data (e.g., scalar integer, scalar floating-point, packed integer, packed floating-point, vector integer, vector floating-point). While some examples may include a number of execution units or execution unit circuitry dedicated to specific functions or sets of functions, other examples may include only one execution unit circuitry or multiple execution units/execution unit circuitry that all perform all functions. The scheduler(s) circuitry 856, physical register file(s) circuitry 858, and execution cluster(s) 860 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) circuitry, and/or execution cluster—and in the case of a separate memory access pipeline, certain examples are implemented in which only the execution cluster of this pipeline has the memory access unit(s) circuitry 864). It should also be understood that where separate pipelines are used, one or more of these pipelines may be out-of-order issue/execution and the rest in-order.

In some examples, the execution engine unit circuitry 850 may perform load store unit (LSU) address/data pipelining to an Advanced Microcontroller Bus (AMB) interface (not shown), and address phase and writeback, data phase load, store, and branches.

The set of memory access circuitry 864 is coupled to the memory unit circuitry 870, which includes data TLB circuitry 872 coupled to data cache circuitry 874 coupled to level 2 (L2) cache circuitry 876. In one example, the memory access circuitry 864 may include load unit circuitry, store address unit circuitry, and store data unit circuitry, each of which is coupled to the data TLB circuitry 872 in the memory unit circuitry 870. The instruction cache circuitry 834 is further coupled to the level 2 (L2) cache circuitry 876 in the memory unit circuitry 870. In one example, the instruction cache circuitry 834 and the data cache circuitry 874 are combined into a single instruction and data cache (not shown) in L2 cache circuitry 876, level 3 (L3) cache circuitry (not shown), and/or main memory. The L2 cache circuitry 876 is coupled to one or more other levels of cache and eventually to a main memory.

The core 890 may support one or more instructions sets (e.g., the x86 instruction set architecture (optionally with some extensions that have been added with newer versions); the MIPS instruction set architecture; the ARM instruction set architecture (optionally with optional additional extensions such as NEON)), including the instruction(s) described herein. In one example, the core 890 includes logic to support a packed data instruction set architecture extension (e.g., AVX1, AVX2), thereby allowing the operations used by many multimedia applications to be performed using packed data.

In some embodiments, the memory devices discussed in connection with FIGS. 5-8 can be configured using the disclosed techniques (e.g., as discussed in connection with FIGS. 9-18).

In some aspects, increasing the capacity in first and second level caches directly enhances the IPC of a high-performance core. Bigger cache size translates into bigger die area, hence higher die cost. Hence, reducing memory area footprint without sacrificing the capacity has motivated semiconductor industry to sacrifice various design for yield and manufacturing rules in these memory modules. At the same time, recent semiconductor technology trend shows that logic devices are scaling at a much faster rate over memory devices. With reduced scaling gap and guided standard cell-based design rules, combination of memory array and random logic floor-planning has become even complicated to share dataflow between two regions. To accommodate equal number of data paths at the same height of memory and logic, extra dummy space is often required in the memory array, further reducing true memory scaling. These technology developments has brought a paradigm shift to memory bitcell and associated peripheral circuit design. Memory designers are ramping up in logic device-based memory array design to reduce wasted area as well as optimize data path design.

With bigger memory capacity, small sized queues and buffers are becoming larger as well. To optimize those medium size array without sacrificing the transparency benefit, static register file is being commonly used instead of latch and flop arrays. Static register files are also designed with logic devices. The disclosed techniques include configuring a single-ended read and a single-ended write register file design. The disclosed techniques also include a contention-free read circuit which allows achieving of similar Vmin of CMOS logic gates as well as improve read delay by 30-40% over traditional design across a PVT range. A description of the operation of this circuit as well as a description of top-level design choices are provided herein, including results and improvement over a current design point.

### Balanced P/N 8T Bitcell and Low Swing Read Circuit

Processor designs can implement numerous 1R1W port memory arrays which constitute approximately 25% of the total die area. These arrays can utilize 8T 1R1W domino-read bitcell (e.g., as illustrated in FIG. 9) having dedicated read ports for improved performance and bitcell read-stability.

FIG. 9 illustrates an 8T domino bitcell 900 configured as a one-read-port-one-write-port (1R1W) bitcell, in accordance with some embodiments. Bitcell 900 can include NMOS transistors 902, 906, 908, and 910, and a cross-coupled inverter pair 904.

In some aspects, domino bitcell layout height does not align with the logic standard cell height and requires dedicated transition regions between every bitcell segment and its peripheral read/write circuitry. Frequently placed transition regions lead to inefficient layouts in processor technologies, which degrades the array area efficiency. Furthermore, conventional 8T bitcells predominantly use NMOS transistors which results in diffusion under-utilization in current diffusion-gridded process technologies. The diffusion under-utilization will be exacerbated in upcoming complementary FET (CFET) technology implementations.

This unbalanced transistor usage would not take full advantage of the area scaling benefits of current CMOS and future CFET technology. The bitcell area scaling would be sub-optimal compared to the corresponding static CMOS logic having balanced number of N and P transistors. Hence, alternative bitcell topologies can be used, which eliminate the need for dedicated transition regions as well as create a balanced P/N bitcells which can enable bitcell area scaling at par with the remaining CMOS standard cell logic gates in current and future processor technologies.

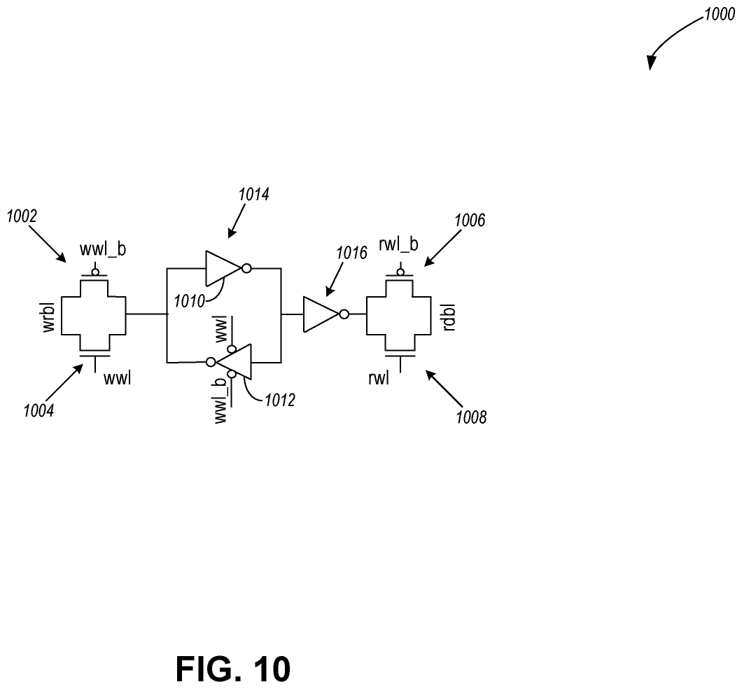

In some aspects, a bitcell choice is a static register file which consists of a single-ended interruptible write port and a single-ended transmission gate based read port with an isolation inverter, as shown in FIG. 10.

FIG. 10 illustrates a 12T static RF bitcell 1000 with interrupted write and isolation inverter in the read port, in accordance with some embodiments. Bitcell 1000 includes PMOS transistors 1002, 1006, NMOS transistors 1004, 1008, an inverter pair 1014 with inverters 1010 and 1012, and an isolation inverter 1016.

The design of bitcell 1000 has fully balanced diffusion usage and is inherently read stable. In some aspects, the design based on 1000 bitcells has an equal number of N and P regions and can be implemented as a CMOS solution. However, leakage power and area impact make it less attractive than a domino bitcell, even with the transition cell penalty. Additionally, such design does not have 100% diffusion usage.

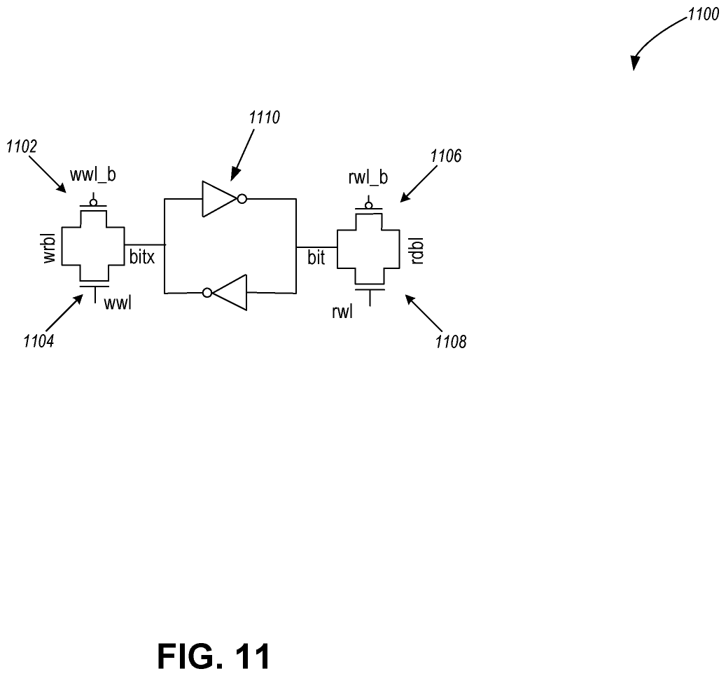

The disclosed techniques include a balanced P/N bitcell (e.g., as illustrated in FIG. 11) which aims at improving the area efficiency and scalability issues for current as well as future 1R1W memory technologies.

FIG. 11 illustrates a balanced P/N 8T bitcell 1100 configured as 1R1W bitcell with a single-ended read mechanism, in accordance with some embodiments. Referring to FIG. 11, bitcell 1100 includes PMOS transistors 1102, 1106, NMOS transistors 1104, 1108, and an inverter pair 1110. As illustrated in FIG. 11, drain terminals of transistors 1102 and 1104 are coupled together to form a single-ended write-bitline (wrbl) terminal for writing digital data into the inverter pair 1110. Similarly, drain terminals of transistors 1106 and 1108 are coupled together to form a single-ended read-bitline (rdbl) terminal for reading digital data stored by the inverter pair 1110.

In some aspects, height, diffusion pattern, and N-well/P-well region distribution of bitcell 1100 can be the same as a standard logic cell layout, along with complete utilization of diffusion regions, thus eliminating the need for transition regions between the bitcell segments and the peripheral read/write circuitry. This configuration can be useful for memory arrays having smaller number of bits/bitline incurring frequent transition regions between the bitcell and the peripheral regions. This bitcell based array design is highly scalable across entry-based memory, enabling rapid proliferation across the memory compiler and easy porting from one logic technology to the next. In some aspects, the same bitcell footprint can be used for 1R1W bitcell using either single-ended or differential read operation to achieve high-performance or high-density array configuration. Since the write operation is a single-ended operation, write-assist such as wordline boost or transient voltage collapse can be used to achieve lower write Vmin.

### Mid-Rail, Single-Ended, Compact Read Sensing Circuits

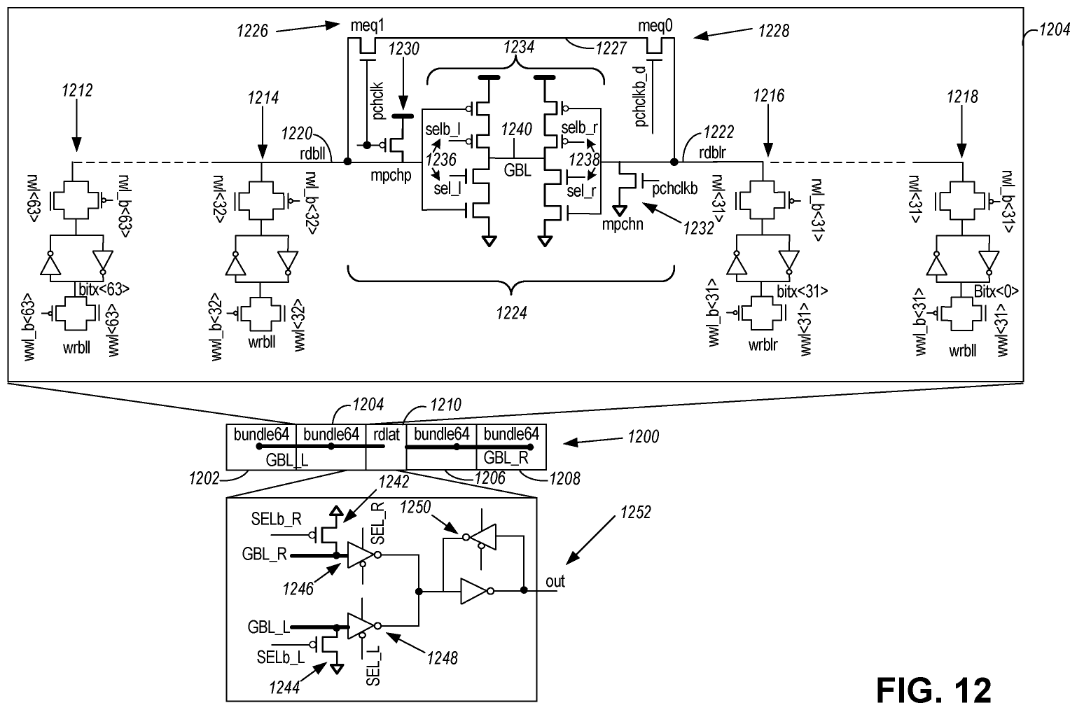

In contrast to a baseline domino 8T bitcell, the disclosed balanced P/N 8T bitcell 1100 adopts a coupled-read mechanism. Hence the bitcell stability during a read operation modes can be guaranteed. Although the bitline may not need to be in a preconditioned state to have a successful read because of push-pull behavior of the read operation, the bitline may be parked at a known state to avoid a floating gate condition at the receiver. With the bitline being at Vdd or ground (GND) voltage, read stability can be compromised since the isolation inverter in the read path of the bitcell is removed. In some aspects, bitcell 1100 can be stable across wide PVT range when the bitline is around mid-rail voltage during a read wordline (RWL) assertion. The lower Vds across the read transmission gate can be associated with a lower read current, hence resulting in stability of the bitcell. The disclosed techniques include a mid-rail, single-ended, and compact read sensing circuits as shown in FIG. 12.

FIG. 12 illustrates a schematic diagram of a 256-entry memory slice 1200 using 1R1W bitcells and single-ended, mid-rail read operation, in accordance with some embodiments. The representative 256-entry memory slice 1200 consists of a read latch 1210 and four bitcell bundles 1202, 1204, 1206, and 1208 with 64 bits in each bundle with local, mid-rail sensing circuits to drive one global bitline (e.g., GBL 1240). FIG. 12 further illustrates details of bundle 1204, with the remaining bundles being configured in a similar way.

Bundle 1204 includes a first plurality of bitcells 1212, . . . , 1214 (also referred to as left-side bitcells) coupled to a first local bitline (LBL) 1220 (also referred to as a left read bitline or rdbll), and a second plurality of bitcells 1216, . . . , 1218 (also referred to as right-side bitcells) coupled to a second LBL 1222 (also referred to as a right read bitline or rdblr). Bundle 1204 further includes a read merge circuit 1224 coupled to the first LBL 1220 and the second LBL 1222. The read merge circuit 1224 includes a first equalizing device 1226 (also referred to as meq1), a second equalizing device 1228 (also referred to as meq0), a pre-charge device 1230, a pre-discharge device 1232, and a feed-forward multiplexing inverter 1234 with a global bitline (GBL) 1240.

The equalizing devices 1226 and 1228 can include NMOS transistors, pre-charge device 1230 can be a PMOS transistor (e.g., with its gate coupled to a gate of equalizing device 1226), and pre-discharge device 1232 can be an NMOS transistor coupled to the second LBL 1222.

In some aspects, the feed-forward multiplexing inverter 1234 includes multiple PMOS and NMOS transistors coupled according to the example configuration illustrated in FIG. 12. In some embodiments, the feed-forward multiplexing inverter 1234 is configured to receive one or more select signals (e.g., select signals 1236 including selb_1 and sel_1) for selecting one of bitlines 1212, . . . , 1214 for performing a read operation, or one or more select signals (e.g., select signals 1238 including selb_r and sel_r) for selecting one of bitlines 1216, . . . , 1218 for performing a read operation. The digital data obtained via the first LBL 1220 or the second LBL 1222 can be multiplexed on the GBL 1240 (along with the corresponding select signals) and communicated to the read latch 1210.

In some embodiments, read latch 1210 includes inverters 1246, 1248, and 1250 as well as transistors 1242 and 1244 configured as illustrated in FIG. 12 to generate an output signal 1252 with the result of the read operation.

In operation, in each bundle (e.g., bundle 1204 of FIG. 12), multiple balanced P/N 8T bitcells are connected to the LBLs rdblr and rdbll. The LBLs are driving the tristate drivers to share the peripheral read circuits enabling a compact read path design. During an example pre-charge phase, rdbll and rdblr are pre-charged (e.g., via pre-charge device 1230) and pre-discharged (e.g., via pre-discharge device 1232) to Vss (supply voltage) and Vdd (ground voltage) respectively.

At the beginning of an evaluate phase, a rise of pchclk turns off mpchp (e.g., the pre-charge device 1230) and fall of pchclkb turns off mpchn (e.g., pre-discharge device 1232). At the same time, pchclk turns meq1 (e.g., equalizing device 1226) ON and since pchclkb_d is still high with meq0 (e.g., equalizing device 1228) turned ON, which results in charge share between rdblr and rdbll via the equalization path 1227 formed between equalization devices 1226 and 1228. After several inversions, pchclkb_d (which can be a buffered version of pchclkb) turns OFF meq0 and cuts off the equalization path 1227 between the two LBLs, just before the read wordline (RWL) is triggered. Since stability of the bitcell becomes vulnerable during a read operation, mid-rail voltage at the local bitline prior the read operation helps/ensures the bitcell stability (this functionality can be an important element to enable the disclosed techniques by eliminating potential read stability failures). Since the bitline voltage is pre-conditioned to mid-rail voltage, read performance is also improved by allowing to charge (or discharge) the LBL during a read “1” (or a read “0”) operation.

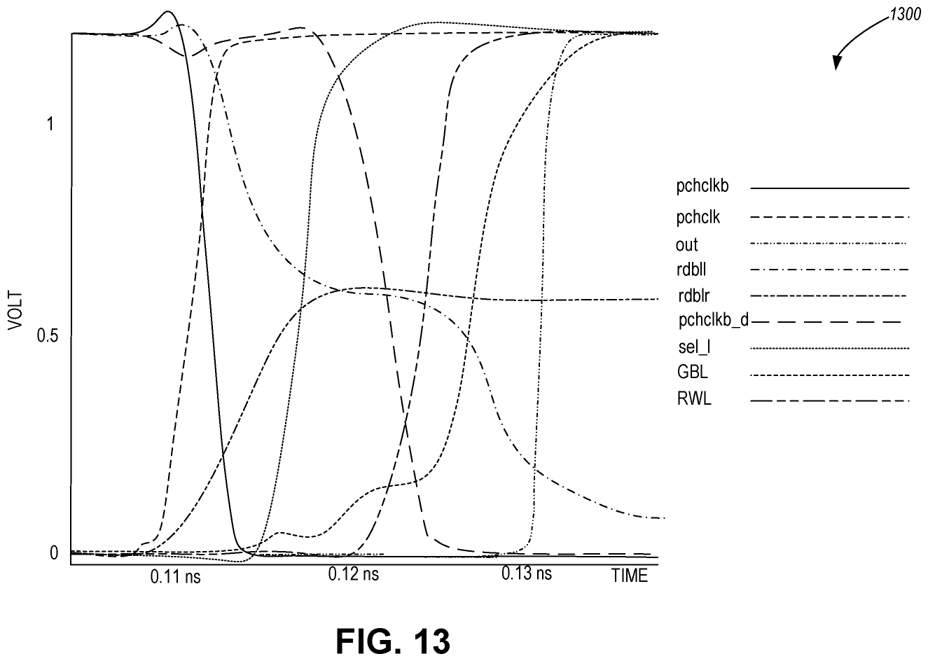

FIG. 13 illustrates a graphical representation 1300 of signals used by the memory device of FIG. 12 during a read “0” operation, in accordance with some embodiments. More specifically, FIG. 13 shows representative simulation waveforms during a read “0” operation in bundle 1204 of FIG. 12. During a pre-charge phase, rdbll and rdblr are parked at pre-charged and pre-discharged voltage levels through mpchp and mpchn devices. At the beginning of a read operation, pchclk rises, mpchp turns OFF and meq1 turns ON. Simultaneously, pchclkb falls to turn OFF mpchn. During this period, both meq0 and meq1 are fully turned ON, while rdbll starts to discharge towards mid-rail voltage with rdblr going up towards mid-rail. Falling of pchclkb_d (buffered version of pchclkb) cuts off the equalization process by turning OFF meq0. At this point, read wordline (RWL) for a selected entry fires and allows the selected bitline to be evaluated based on the content of the bitcell. In this example, rdbll is going down since selected bitcell is storing “0” at the bit node. Since one of the left-side bitcells has been selected, selection signals sel_1 and selb_1 allow the evaluated rdbll value to be propagated to the global bitline GBL 1240, storing the output at the read data latch 1210 and generating the output signal 1252.

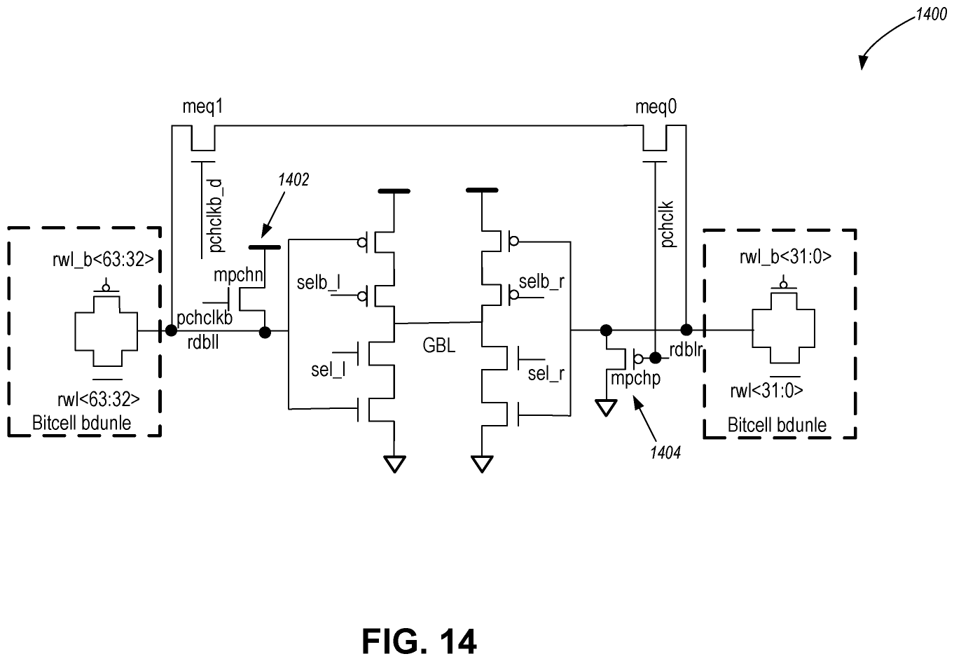

FIG. 14 illustrates a schematic diagram 1400 of a different embodiment of a 256-entry bundle using 1R1W bitcells and single-ended, mid-rail read operation, in accordance with some embodiments. More specifically, the bundle in FIG. 14 can be substantially similar to bundle 1204 of FIG. 12, with a different configuration of the pre-charge and pre-discharge devices. More specifically, the bundle in FIG. 14 uses a pull-up NMOS transistor as the pre-charge device 1402 and a pull-down PMOS transistor as the pre-discharge device 1404. The corresponding clock signals input to the gates of the equalizing devices meq1 and meq0 are also reversed in comparison to FIG. 12.

In this regard, FIG. 14 illustrates a lower-power variant of the above mentioned read-merge circuit of FIG. 12, realized using a PMOS based pull-down and NMOS based pull-up circuit. Use of PMOS pull-down transistor (mpchp) and NMOS pull-up transistor (mpchn) allow the LBLs to stay at Vss+VthP and Vdd−VthN voltage respectively. Pre-charging less than Vdd and pre-discharging above ground voltage can reduce overall dynamic power during the pre-charge phase. This configuration also cuts down the leakage current through the bitcells.

In some aspects, PMOS pull-down and NMOS pull-up transistors may take relatively longer time to pre-discharge and pre-charge the bitline voltage from a previous read operation. However, equalization of the two bitlines through NMOS (e.g., via meq0 and meq1) will be faster, compensating for any performance loss.

### Process-Variation Resilient, Low-Leakage, High-Performance Simultaneous Pre-charge-Evaluate Read Circuit for Register File

Recent demand in high bandwidth and lower memory latency requirements in microprocessor for server and data center application may include incorporating larger size high-density memory modules within the same die. Large memory footprint costs larger die area as well as higher budget for leakage and dynamic power. In order to meet higher performance during turbo operation and also be within leakage budget during idle period, most state-of-the art processors have a dynamic voltage-frequency scaling-based (DVFS) power state management unit which can control separate core and memory blocks across wide range of voltage and power states. Hence, memory arrays are desired to optimize for high performance at high voltage as well as Vmin as close to logic device Vmin. In sub-14-nm process node, both inter-die and intra-die process variation has become another challenge and requires putting additional guardband to meet min-max timing margin across wide voltage range. To meet such power-performance-area (PPA) criteria, memory designers are constantly looking for ways to cut down leakage current without sacrificing performance with robust circuit operation against global and local process variations.

The disclosed techniques can be used to configure a register file read circuit which allows for improvement of the read delay by 20-50% over a traditional design across PVT range and reducing leakage current by 30% from traditional 1R1W RF array design as well as exceeding area metrics compared traditional design style. The disclosed techniques also allow for decoupling process variation guardband in clock to delay path which impacts the Fmax/IPC of the chip. The operation of this circuit and a description of top-level design choices are provided herein below.

In memory design, performance is a key consideration since memory latency can directly impact overall chip performance. To ensure the performance metric is met and to design robust memory circuits to operate at a wide PVT range, designs are typically verified and modeled at global common and skew corners with local variation of 6-sigma. Hence, worst case static timing analysis may be used for the whole circuit to guarantee correct functionality at the worst delay point.

Leakage power minimization is another important key choice during design space exploration. Several common leakage saving features are normally utilized such as use of high-Vt low-leakage devices in less performance critical part of the design, stacking of transistors such as wordline drivers, floating bitline in SRAM and register files, and fine-grain sleep region using power-gated or diode-connected devices. In RF design, typically low-Vt transistor read stack is used which is major contributor to array leakage. Floating bitline is a technique to reduce read stack leakage power and can be implemented using Mega-merge (MM) based RF arrays on processor products. However, this may impact address setup time so that a selected bitline can be pre-charged prior to the read wordline (RWL) being asserted.

The disclosed read circuit addresses the above-mentioned drawbacks without any extra area cost over a traditional 1R1W design by improving the read delay based on controlling the read path through logic gates as well as keeping the leakage power reduction to minimum point by keeping the read bitline parked at ground voltage during the non-evaluate phase. Additionally, the clock-to-output delay path goes through the non-memory devices, which increases the circuit's robustness against process variation and removes the design timing guard-banding.

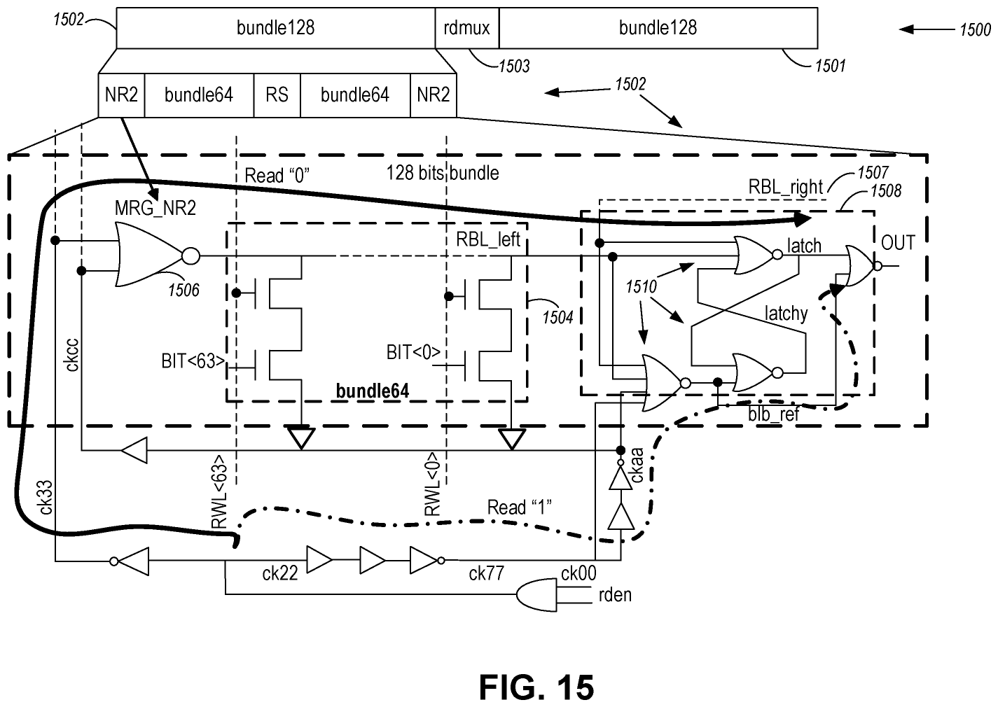

FIG. 15 illustrates a schematic diagram of a simultaneous pre-charge-evaluate circuit, in accordance with some embodiments. Referring to FIG. 15, memory slice 1500 includes 128-bit bitcell bundles 1502 and 1501 as well as a read multiplexer 1503. As illustrated in FIG. 15, bundle 1502 includes read bitlines (RBLs) 1504 (also referred to as RBL_left) and 1507 (also referred to as RBL_right which is not fully illustrated in FIG. 15). Bundle 1502 further includes a NOR gate 1506 and a latch circuit 1508 (also referred to as RS latch) with logic gates 1510.

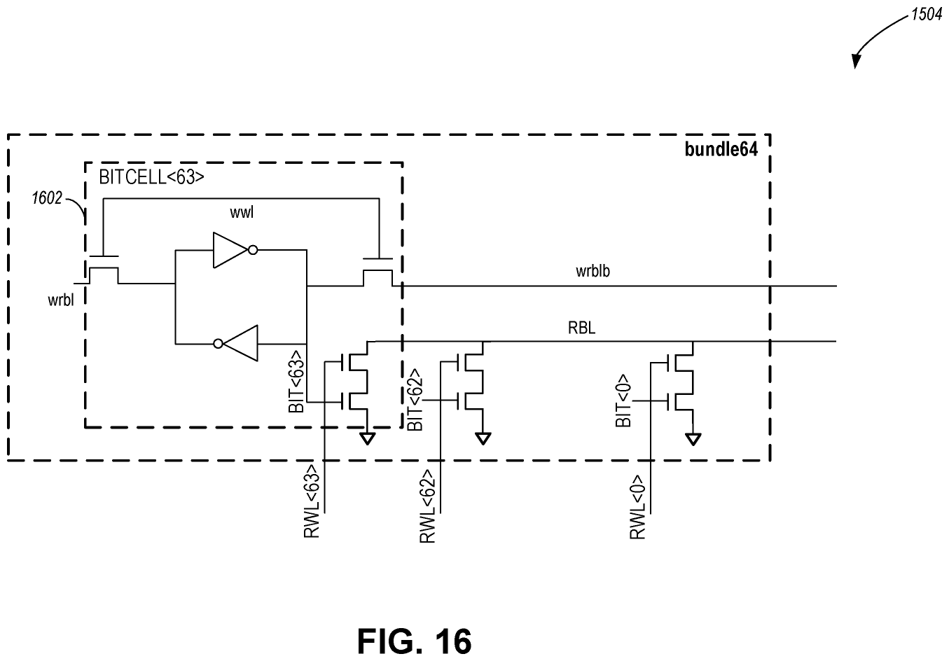

A more detailed diagram of bundle 1504 is illustrated in FIG. 16. FIG. 16 illustrates a schematic diagram of a bitcell bundle used by the circuit of FIG. 15, in accordance with some embodiments. In some aspects, bundle 1504 includes a plurality of bitcells such as bitcell 1602. In some aspects, bitcell 1602 can be configured according to the techniques disclosed herein.

FIG. 15 shows a schematic block diagram of an 128-bit entry array slice using simultaneous pre-charge-evaluate read technique. In some aspects, the 256-bit slice includes two 128-bit bundles where 64 1R1W bitcells are connected to the left and right read bitlines in each bundle. The two read bitlines (RBL_left and RBL_right) are merged at the set input cone of the RS latch. The reset cone is driven by a 4-input NOR gate (e.g., one of logic gates 1510) which is controlled by the read bitlines along with reset clocks. A two-input NOR gate 1506 (MRG_NR2) is driven by read clock ck33 and read reset clock ckcc. Each read bitline can be driven by the output of MRG_NR2, which holds the bitlines to ground during the non-evaluate phase.

In some aspects, clock ck22 is a gated clock, enabled by the rden input and is propagated to the selected bundle in a 256-entry slice based on higher order address. Read operation starts with a falling of ck33, which is an inverted version of ck22.

During a read “0” operation, the following functionality is performed. As a read clock is fired, ck33 falls to “0” and ckcc is initially “0”. This causes MRG_NR2 to drive the RDBL high. Since the bit node is “0”, the RDBL is driven to “1” as the bitcell read stack path is cut off. As RBL goes high, RS latch gets “set” and read data is registered in the latch as the “latch” node goes down. It can be an important configuration that the reset clock ck77 stays high during this time for proper latching of the high RBL value into the RS latch. During design phase, a healthy setup margin is configured such that RBL reaches to 80% of vcc prior to beginning of the falling of ck77. Clock ckaa is a delayed inverted version of the ck77, which closes the RS latch reset port. Once ckaa rises, it is safe to turn the bitline back to non-evaluate, pre-discharged state to ground by asserting ckcc into the input of the MRG_NR2. The arrival of ckcc can be used to prevent the resetting value of the bitline from racing through the latch.

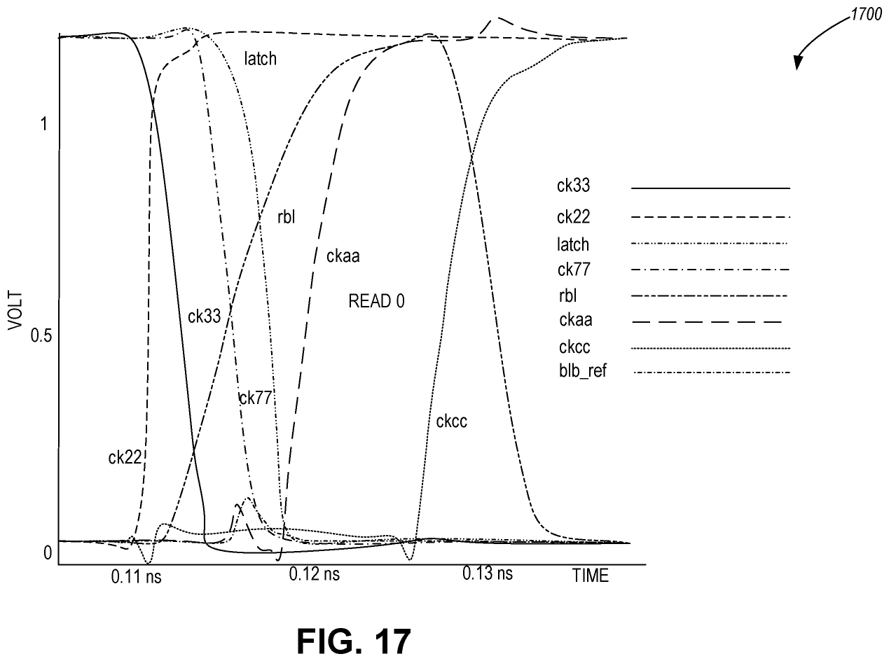

FIG. 17 illustrates a graphical representation 1700 of signals used by the circuit of FIG. 15 during a read “0” operation, in accordance with some embodiments.

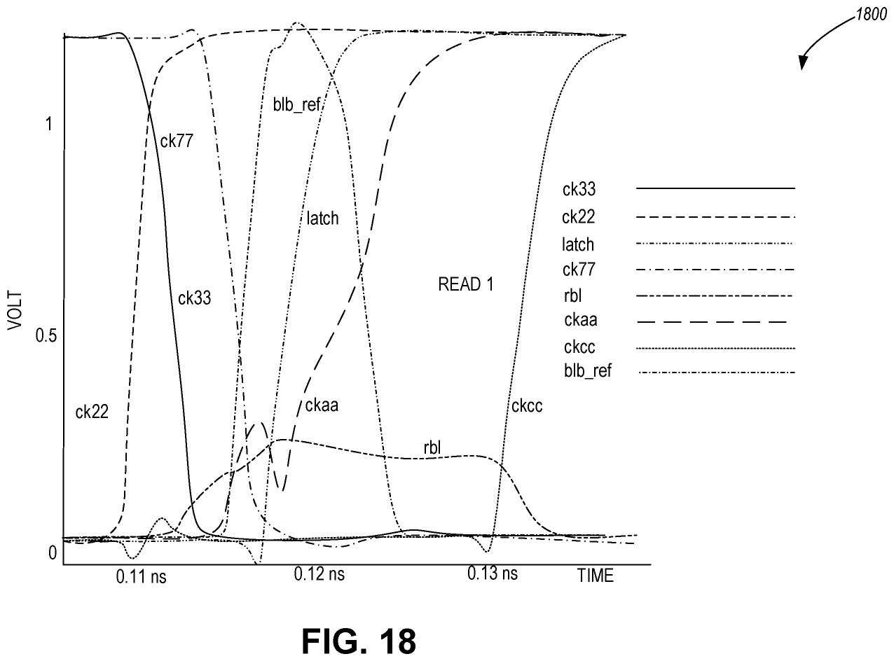

FIG. 18 illustrates a graphical representation 1800 of signals used by the circuit of FIG. 15 during a read “1” operation, in accordance with some embodiments.

During the example read “1” operation, a read clock is asserted and ck33 falls to “0”. Read wordline is already ON and setup to the falling of ck33, and hence devices in the read stack are ON. The falling edge of ck33 triggers a contention between pull down read stack and weak pull device in MRG_NR2. The pull-up to pull-down ratio is designed to keep the read bitline voltage below 20% across wide PVT range in the presence of process variation. While the bitline is in a contention state, ck77 falls to reset the latch by bringing blb_ref high. The node ‘blb_ref’ brings “latch” node high and propagates the read value to the output “OUT”. The ckaa clock signal comes and closes the reset port of RS latch, followed by ckcc to reset the read bitline back to ground.

In some aspects, interlock between the four clocks is built-in in the decode from the same point of divergence so that all the margins are clean by construction. The distance between the falling edge of ck33 and ck77 is defined by the bitline rise time during the read “0” operation. Since all read paths are determined by clock paths, special attention has been put for appropriate clock path shielding during layout.

In some embodiments, a 256-bit entry by 88 bits memory array can be built using the disclosed read technique. Since read wordlines are not clock-like signals, read decoder design is flexible and relaxed in terms of wordline driver strength. In some aspects, wordline drivers can be double stacked to reduce leakage since a wordline driver contributes up to 10% of the leakage in this typical size of memory array.

Since read stack of the bitcell is decoupled from the clock-to-output delay path, the array supply voltage can be reduced to further cutdown bitcell leakage without sacrificing read performance. Reduced array supply can also work as write-assist and can replace a “P-shared” write assist.

Since the true clock (ckcc) and the inverted clock (ck33) are merged at the MRG_NR2, traditional formal verification tool may not be used to formally verify the logical equivalence of the circuit with RTL model. Full symbolic dual phase testbench based verification can be used using “ESPCV” tool. The primary inputs can be applied with random symbols at each phase and output compare is performed between RTL golden model and circuit netlist based on formal equation. Static timing analysis on this block may be challenging, and the clock edges can be configured to trace the output path correctly. In some aspects, custom arc overrides are placed to trace latch node falling through ck33 falling and rising through ck77 falling respectively. Several custom checks are also applied to close the internal margin through the static timing analysis.

FIG. 19 illustrates a block diagram of an example machine 1900 upon which any one or more of the techniques (e.g., methodologies) discussed herein may perform. In alternative embodiments, the machine 1900 may operate as a standalone device or may be connected (e.g., networked) to other machines. In a networked deployment, machine 1900 may operate in the capacity of a server machine, a client machine, or both in server-client network environments. In an example, the machine 1900 may act as a peer machine in a peer-to-peer (P2P) (or other distributed) network environment. The machine 1900 may be a personal computer (PC), a tablet PC, a set-top box (STB), a personal digital assistant (PDA), a portable communications device, a mobile telephone, a smartphone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Machine (e.g., computer system) 1900 may include a hardware processor 1902 (e.g., a central processing unit (CPU), a graphics processing unit (GPU), a hardware processor core, or any combination thereof), a main memory 1904, and a static memory 1906, some or all of which may communicate with each other via an interlink (e.g., bus) 1908. In some aspects, the main memory 1904, the static memory 1906, or any other type of memory (including cache memory) used by the machine 1900 can be configured based on the disclosed techniques or can implement the disclosed memory devices.

Specific examples of main memory 1904 include Random Access Memory (RAM), and semiconductor memory devices, which may include, in some embodiments, storage locations in semiconductors such as registers. Specific examples of static memory 1906 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1900 may further include a display device 1910, an input device 1912 (e.g., a keyboard), and a user interface (UI) navigation device 1914 (e.g., a mouse). In an example, the display device 1910, input device 1912, and UI navigation device 1914 may be a touch screen display. The machine 1900 may additionally include a storage device (e.g., drive unit or another mass storage device) 1916, a signal generation device 1918 (e.g., a speaker), a network interface device 1920, and one or more sensors 1921, such as a global positioning system (GPS) sensor, compass, accelerometer, or other sensors. The machine 1900 may include an output controller 1928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the processor 1902 and/or instructions 1924 may comprise processing circuitry and/or transceiver circuitry.

The storage device 1916 may include a machine-readable medium 1922 on which is stored one or more sets of data structures or instructions 1924 (e.g., software) embodying or utilized by any one or more of the techniques or functions described herein. The instructions 1924 may also reside, completely or at least partially, within the main memory 1904, within static memory 1906, or within the hardware processor 1902 during execution thereof by the machine 1900. In an example, one or any combination of the hardware processor 1902, the main memory 1904, the static memory 1906, or the storage device 1916 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1922 is illustrated as a single medium, the term “machine-readable medium” may include a single medium or multiple media (e.g., a centralized or distributed database, and/or associated caches and servers) configured to store one or more instructions 1924.

An apparatus of the machine 1900 may be one or more of a hardware processor 1902 (e.g., a central processing unit (CPU), a graphics processing unit (GPU), a hardware processor core, or any combination thereof), a main memory 1904 and a static memory 1906, one or more sensors 1921, a network interface device 1920, antennas 1960, a display device 1910, an input device 1912, a UI navigation device 1914, a storage device 1916, instructions 1924, a signal generation device 1918, and an output controller 1928. The apparatus may be configured to perform one or more of the methods and/or operations disclosed herein. The apparatus may be intended as a component of the machine 1900 to perform one or more of the methods and/or operations disclosed herein, and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by the machine 1900 and that causes the machine 1900 to perform any one or more of the techniques of the present disclosure, or that is capable of storing, encoding or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1924 may further be transmitted or received over a communications network 1926 using a transmission medium via the network interface device 1920 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 1920 may include one or more physical jacks (e.g., Ethernet, coaxial, or phone jacks) or one or more antennas to connect to the communications network 1926. In an example, the network interface device 1920 may include one or more antennas 1960 to wirelessly communicate using at least one single-input multiple-output (SIMO), multiple-input multiple-output (MIMO), or multiple-input single-output (MISO) techniques. In some examples, the network interface device 1920 may wirelessly communicate using Multiple User MIMO techniques. The term “transmission medium” shall be taken to include any intangible medium that is capable of storing, encoding, or carrying instructions for execution by the machine 1900, and includes digital or analog communications signals or other intangible media to facilitate communication of such software.

Examples, as described herein, may include, or may operate on, logic or a number of components, modules, or mechanisms. Modules are tangible entities (e.g., hardware) capable of performing specified operations and may be configured or arranged in a certain manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programed) to operate in a specified manner or to perform part or all of any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at different times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM); random access memory (RAM); magnetic disk storage media; optical storage media; flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in a number of environments such as part of a wireless local area network (WLAN), 3rd Generation Partnership Project (3GPP) Universal Terrestrial Radio Access Network (UTRAN), or Long-Term-Evolution (LTE) or a Long-Term-Evolution (LTE) communication system, although the scope of the disclosure is not limited in this respect.

Antennas referred to herein may comprise one or more directional or omnidirectional antennas, including, for example, dipole antennas, monopole antennas, patch antennas, loop antennas, and microstrip antennas, or other types of antennas suitable for transmission of RF signals. In some embodiments, instead of two or more antennas, a single antenna with multiple apertures may be used. In these embodiments, each aperture may be considered a separate antenna. In some multiple-input multiple-output (MIMO) embodiments, antennas may be effectively separated to take advantage of spatial diversity and the different channel characteristics that may result between each antenna and the antennas of a transmitting station. In some MIMO embodiments, antennas may be separated by up to 1/10 of a wavelength or more.

Described implementations of the subject matter can include one or more features, alone or in combination as illustrated below by way of examples.
Example 1 is a memory device comprising: at least one bitcell coupled to a local bitline, the at least one bitcell comprising: a first set of a plurality of transistor devices configured to form a single write (1W) port, the 1W port to receive digital data; a second set of the plurality of transistor devices configured as an inverter pair, the inverter pair to store the digital data; and a third set of the plurality of transistor devices configured to form a single read (1R) port, the 1R port to access the digital data stored at the inverter pair and output the digital data on the local bitline, and the plurality of transistor devices consisting of an equal number of P-channel transistor devices and N-channel transistor devices.
In Example 2, the subject matter of Example 1 includes subject matter where the plurality of transistor devices consists of four N-channel metal-oxide semiconductor (NMOS) transistors and four P-channel metal-oxide semiconductor (PMOS) transistors.
In Example 3, the subject matter of Example 2 includes subject matter where the first set of the plurality of transistor devices consists of a first NMOS transistor of the four NMOS transistors and a first PMOS transistor of the four PMOS transistors.
In Example 4, the subject matter of Example 3 includes, W port is formed by drain terminals of the first NMOS transistor and the first PMOS transistor.
In Example 5, the subject matter of Example 4 includes subject matter where a gate terminal of the first NMOS transistor forms a write-wordline (wwl) terminal and a gate terminal of the first PMOS transistor forms a write-wordline-bar (wwl_b) terminal, the wwl terminal and the wwl_b terminal associated with writing the digital data into the inverter pair.
In Example 6, the subject matter of Examples 3-5 includes subject matter where the third set of the plurality of transistor devices consists of a second NMOS transistor of the four NMOS transistors and a second PMOS transistor of the four PMOS transistors.
In Example 7, the subject matter of Example 6 includes, R port is formed by drain terminals of the second NMOS transistor and the second PMOS transistor.
Example 8 is a memory device comprising: a first plurality of bitcells coupled via a first local bitline (LBL); a second plurality of bitcells coupled via a second LBL, each bitcell of the plurality of bitcells and the second plurality of bitcells comprising a single read (1R) port and a single write (1W) port; and read merge circuitry coupled to the first LBL and the second LBL, the read merge circuitry to perform operations comprising: pre-charging a node of the first LBL to a first supply voltage; pre-discharging a node of the second LBL to a second supply voltage; activating an equalization path between the first LBL and the second LBL, the activating of the equalization path causing charge sharing between the node of the first LBL and the node of the second LBL; detecting a read wordline (RWL) for a selected bitcell of the first plurality of bitcells or the second plurality of bitcells; and performing a read operation of the selected bitcell based on the detecting of the RWL.
In Example 9, the subject matter of Example 8 includes subject matter where the read merge circuitry further comprises: a P-channel metal-oxide semiconductor (PMOS) transistor configured as a pre-charge device.
In Example 10, the subject matter of Example 9 includes subject matter where the pre-charge device is configured to perform the pre-charging of the node of the first LBL to the first supply voltage during a pre-charging phase of the read merge circuitry.
In Example 11, the subject matter of Example 10 includes subject matter where the read merge circuitry further comprises: a first N-channel metal-oxide semiconductor (NMOS) transistor configured as a pre-discharge device.
In Example 12, the subject matter of Example 11 includes subject matter where the pre-discharge device is configured to perform the pre-discharging of the node of the second LBL to the second supply voltage during the pre-charging phase of the read merge circuitry.
In Example 13, the subject matter of Examples 11-12 includes subject matter where the read merge circuitry further comprises: a first equalizing device coupled to the node of the first LBL; and a second equalizing device coupled to the node of the second LBL, wherein the first equalizing device and the second equalizing device are further coupled to each other to form the equalization path.
In Example 14, the subject matter of Example 13 includes subject matter where the first equalizing device comprises a second NMOS transistor, the second equalizing device comprises a third NMOS transistor, and wherein a gate of the second NMOS transistor is coupled to a gate of the first NMOS transistor.
In Example 15, the subject matter of Example 14 includes subject matter where to activate the equalization path, the read merge circuitry further performs operations comprising: asserting a first clock signal at the gate of the second NMOS transistor and the gate of the first NMOS transistor to activate the first equalizing device and deactivate the pre-charge device.
In Example 16, the subject matter of Example 15 includes subject matter where to activate the equalization path, the read merge circuitry further performs operations comprising: asserting a buffered version of a second clock signal at the gate of the third NMOS transistor, the second clock signal being asserted at a gate of the first NMOS transistor.
In Example 17, the subject matter of Examples 8-16 includes subject matter where the read merge circuitry further comprises: a feed-forward multiplexing inverter coupled to the first LBL and the second LBL, the feed-forward multiplexing inverter comprising a global bitline (GBL) configured to receive digital data from one the first plurality of bitcells via the first LBL or from one of the second plurality of bitcells via the second LBL.
Example 18 is a memory device comprising: a first plurality of bitcells coupled via a first local bitline (LBL); a second plurality of bitcells coupled via a second LBL, each bitcell of the plurality of bitcells and the second plurality of bitcells comprising a single read (1R) port and a single write (1W) port; and read merge circuitry coupled to the first LBL and the second LBL, the read merge circuitry comprising: a pre-charge device coupled to the first LBL, the pre-charge device configured to pre-charge a node of the first LBL to a first supply voltage during a pre-charging phase of the read merge circuitry; a pre-discharge device coupled to the second LBL, the pre-discharge device configured to pre-discharge a node of the second LBL to a second supply voltage during the pre-charging phase; and an equalization path configured between the first LBL and the second LBL, the equalization path causing prior to a read operation, charge sharing between the node of the first LBL and the node of the second LBL and equalizing a voltage on the first LBL and a voltage on the second LBL to a voltage level between the first supply voltage and the second supply voltage.
In Example 19, the subject matter of Example 18 includes subject matter where the pre-charge device is a P-channel metal-oxide semiconductor (PMOS) transistor, and wherein the pre-discharge device is a N-channel metal-oxide semiconductor (NMOS) transistor.
In Example 20, the subject matter of Examples 18-19 includes subject matter where the read merge circuitry further comprises: a first equalizing device coupled to the node of the first LBL; and a second equalizing device coupled to the node of the second LBL, wherein the first equalizing device and the second equalizing device are further coupled to each other to form the equalization path.
In Example 21, the subject matter of Example 20 includes subject matter where the first equalizing device comprises a N-channel metal-oxide semiconductor (NMOS) transistor, and wherein a gate of the NMOS transistor is coupled to a gate of the pre-charge device.
In Example 22, the subject matter of Examples 18-21 includes subject matter where the read merge circuitry further comprises: a feed-forward multiplexing inverter coupled to the first LBL and the second LBL, the feed-forward multiplexing inverter comprising a global bitline (GBL) configured to receive digital data from at least one bitcell selected from one the first plurality of bitcells via the first LBL or from one of the second plurality of bitcells via the second LBL, and communicate the data and at least one select signal selecting the at least one bitcell to a read latch.
Example 23 is at least one machine-readable medium including instructions that, when executed by processing circuitry, cause the processing circuitry to perform operations to implement any of Examples 1-22.
Example 24 is an apparatus comprising means to implement any of Examples 1-22.
Example 25 is a system to implement any of Examples 1-22.
Example 26 is a method to implement any of Examples 1-22.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. A memory device comprising:
at least one bitcell coupled to a local bitline, the at least one bitcell comprising:
a first set of a plurality of transistor devices configured to form a single write (1W) port, the 1W port to receive digital data;
a second set of the plurality of transistor devices configured as an inverter pair, the inverter pair to store the digital data; and
a third set of the plurality of transistor devices configured to form a single read (1R) port, the 1R port to access the digital data stored at the inverter pair and output the digital data on the local bitline, and the plurality of transistor devices consisting of an equal number of P-channel transistor devices and N-channel transistor devices.

2. The memory device of claim 1, wherein the plurality of transistor devices consists of four N-channel metal-oxide semiconductor (NMOS) transistors and four P-channel metal-oxide semiconductor (PMOS) transistors.

3. The memory device of claim 2, wherein the first set of the plurality of transistor devices consists of a first NMOS transistor of the four NMOS transistors and a first PMOS transistor of the four PMOS transistors.

4. The memory device of claim 3, wherein the 1W port is formed by drain terminals of the first NMOS transistor and the first PMOS transistor.

5. The memory device of claim 4, wherein a gate terminal of the first NMOS transistor forms a write-wordline (wwl) terminal and a gate terminal of the first PMOS transistor forms a write-wordline-bar (wwl_b) terminal, the wwl terminal and the wwl_b terminal associated with writing the digital data into the inverter pair.

6. The memory device of claim 3, wherein the third set of the plurality of transistor devices consists of a second NMOS transistor of the four NMOS transistors and a second PMOS transistor of the four PMOS transistors.

7. The memory device of claim 6, wherein the 1R port is formed by drain terminals of the second NMOS transistor and the second PMOS transistor.

8. A memory device comprising:
a first plurality of bitcells coupled via a first local bitline (LBL);
a second plurality of bitcells coupled via a second LBL, each bitcell of the plurality of bitcells and the second plurality of bitcells comprising a single read (1R) port and a single write (1W) port; and
read merge circuitry coupled to the first LBL and the second LBL, the read merge circuitry to perform operations comprising:
pre-charging a node of the first LBL to a first supply voltage;
pre-discharging a node of the second LBL to a second supply voltage;
activating an equalization path between the first LBL and the second LBL, the activating of the equalization path causing charge sharing between the node of the first LBL and the node of the second LBL;
detecting a read wordline (RWL) for a selected bitcell of the first plurality of bitcells or the second plurality of bitcells; and
performing a read operation of the selected bitcell based on the detecting of the RWL.

9. The memory device of claim 8, wherein the read merge circuitry further comprises:
a P-channel metal-oxide semiconductor (PMOS) transistor configured as a pre-charge device.

10. The memory device of claim 9, wherein the pre-charge device is configured to perform the pre-charging of the node of the first LBL to the first supply voltage during a pre-charging phase of the read merge circuitry.

11. The memory device of claim 10, wherein the read merge circuitry further comprises:
a first N-channel metal-oxide semiconductor (NMOS) transistor configured as a pre-discharge device.

12. The memory device of claim 11, wherein the pre-discharge device is configured to perform the pre-discharging of the node of the second LBL to the second supply voltage during the pre-charging phase of the read merge circuitry.

13. The memory device of claim 11, wherein the read merge circuitry further comprises:
a first equalizing device coupled to the node of the first LBL; and
a second equalizing device coupled to the node of the second LBL, wherein the first equalizing device and the second equalizing device are further coupled to each other to form the equalization path.

14. The memory device of claim 13, wherein the first equalizing device comprises a second NMOS transistor, the second equalizing device comprises a third NMOS transistor, and wherein a gate of the second NMOS transistor is coupled to a gate of the first NMOS transistor.

15. The memory device of claim 14, wherein to activate the equalization path, the read merge circuitry further performs operations comprising:
asserting a first clock signal at the gate of the second NMOS transistor and the gate of the first NMOS transistor to activate the first equalizing device and deactivate the pre-charge device.

16. The memory device of claim 15, wherein to activate the equalization path, the read merge circuitry further performs operations comprising:
asserting a buffered version of a second clock signal at the gate of the third NMOS transistor, the second clock signal being asserted at a gate of the first NMOS transistor.

17. The memory device of claim 8, wherein the read merge circuitry further comprises:
a feed-forward multiplexing inverter coupled to the first LBL and the second LBL, the feed-forward multiplexing inverter comprising a global bitline (GBL) configured to receive digital data from one the first plurality of bitcells via the first LBL or from one of the second plurality of bitcells via the second LBL.

18. A memory device comprising:
a first plurality of bitcells coupled via a first local bitline (LBL);
a second plurality of bitcells coupled via a second LBL, each bitcell of the plurality of bitcells and the second plurality of bitcells comprising a single read (1R) port and a single write (1W) port; and
read merge circuitry coupled to the first LBL and the second LBL, the read merge circuitry comprising:
a pre-charge device coupled to the first LBL, the pre-charge device configured to pre-charge a node of the first LBL to a first supply voltage during a pre-charging phase of the read merge circuitry;
a pre-discharge device coupled to the second LBL, the pre-discharge device configured to pre-discharge a node of the second LBL to a second supply voltage during the pre-charging phase; and
an equalization path configured between the first LBL and the second LBL, the equalization path causing prior to a read operation, charge sharing between the node of the first LBL and the node of the second LBL and equalizing a voltage on the first LBL and a voltage on the second LBL to a voltage level between the first supply voltage and the second supply voltage.

19. The memory device of claim 18, wherein the pre-charge device is a P-channel metal-oxide semiconductor (PMOS) transistor, and wherein the pre-discharge device is an N-channel metal-oxide semiconductor (NMOS) transistor.

20. The memory device of claim 18, wherein the read merge circuitry further comprises:
a first equalizing device coupled to the node of the first LBL; and
a second equalizing device coupled to the node of the second LBL, wherein the first equalizing device and the second equalizing device are further coupled to each other to form the equalization path.

21. The memory device of claim 20, wherein the first equalizing device comprises a N-channel metal-oxide semiconductor (NMOS) transistor, and wherein a gate of the NMOS transistor is coupled to a gate of the pre-charge device.

22. The memory device of claim 18, wherein the read merge circuitry further comprises:
a feed-forward multiplexing inverter coupled to the first LBL and the second LBL, the feed-forward multiplexing inverter comprising a global bitline (GBL) configured to receive digital data from at least one bitcell selected from one the first plurality of bitcells via the first LBL or from one of the second plurality of bitcells via the second LBL, and communicate the data and at least one select signal selecting the at least one bitcell to a read latch.
